(19) United States
(12) Patent Application Publication
(10) Pub. No.: US 2024/0324360 A1
(43) Pub. Date: Sep. 26, 2024

(54) DISPLAY DEVICE AND DISPLAY PANEL

(71) Applicant: LG Display Co., Ltd., Seoul (KR)

(72) Inventors: SungJin PARK, Paju-si (KR); HoYoung LEE, Paju-si (KR); SeungHyun LEE, Paju-si (KR)

(21) Appl. No.: 18/608,585

(22) Filed: Mar. 18, 2024

(30) Foreign Application Priority Data
Mar. 21, 2023 (KR) 10-2023-0036778

(51) Int. Cl. H10K 59/131; H10K 59/122; H10K 59/40; H10K 59/65; H10K 59/80

(52) U.S. Cl. CPC H10K 59/131; H10K 59/122; H10K 59/40; H10K 59/65; H10K 59/873

(57) ABSTRACT

Embodiments of the disclosure relate to a display panel and a display device that may provide a line characteristic deviation reduction structure and a transmittance variation range reduction structure. The device includes signal lines and a common electrode on the substrate. The display area of the device includes a first optical area where light is transmitted, and a normal area positioned outside the first optical area. The normal area includes emission areas, and the first optical area includes emission areas and first transmissive areas. The common electrode includes common electrode holes respectively positioned in the first transmissive areas. The signal lines include normal signal lines not passing through the first optical area and disposed only in the normal area, and specific signal lines passing through the first optical area. Each specific signal lines overlap at least one common electrode holes.

### CROSS-REFERENCE TO RELATED APPLICATION

This application claims priority from Korean Patent Application No. 10-2023-0036778, filed on Mar. 21, 2023, which is hereby incorporated by reference for all purposes as if fully set forth herein.

### BACKGROUND

### Technical Field

Embodiments of the disclosure relate to a display device and a display panel.

### Description of the Related Art

With the development of technology, the display device may provide a capture function and various detection functions in addition to an image display function. To this end, the display device includes an optical electronic device (also referred to as a light receiving device or sensor), such as a camera and a detection sensor.

The optical electronic device should be installed at a position where it is able to receive light since it needs to receive light from the front surface of the display device. In the conventional display device, therefore, the camera (camera lens) and the detection sensor end up being exposed to the front surface. As a result, the bezel of the display device may increase, or design of the display device may be significantly limited.

### BRIEF SUMMARY

Embodiments of the disclosure may provide a display panel and a display device, in which an optical electronic device has a light transmission structure capable of normally receiving light (e.g., visible light, infrared light, or ultraviolet light), and the optical electronic device is not exposed to the front surface.

Embodiments of the disclosure may provide a display panel and a display device having a line characteristic deviation reduction structure between an optical area where light may be transmitted and a normal area where light is not transmitted.

Embodiments of the disclosure may provide a display panel and a display device having a transmittance variation reduction structure in an optical area where light may be transmitted.

A display device according to embodiments of the disclosure may comprise a substrate including a display area displaying an image, a plurality of signal lines disposed on the substrate, and a common electrode disposed on the substrate.

The display area may include a first optical area where light is transmitted and a normal area positioned outside or around the first optical area.

The normal area may include a plurality of emission areas.

The first optical area may include a plurality of emission areas and a plurality of first transmissive areas.

The common electrode may include a plurality of common electrode holes respectively positioned in the plurality of first transmissive areas.

The plurality of signal lines may include a plurality of normal signal lines not passing through the first optical area and disposed only in the normal area and a plurality of specific signal lines passing through the first optical area.

Each of the plurality of specific signal lines may overlap at least one of the plurality of common electrode holes.

A display panel according to embodiments of the disclosure may comprise a substrate including a display area displaying an image and a plurality of signal lines disposed on the substrate.

The display area may include a first optical area where light is transmitted and a normal area different from the first optical area.

The normal area may include a plurality of emission areas.

The first optical area may include a plurality of emission areas and a plurality of first transmissive areas.

The plurality of signal lines may include a normal signal line not passing through the first optical area and a specific signal line passing through the first optical area and disposed parallel to the normal signal line.

The specific signal line may have the same length as the normal signal line.

Here, that the specific signal line has the same length as the normal signal line may mean that that the length of the specific signal line is completely the same as the length of the normal signal line. Alternatively, that the specific signal line has the same length as the normal signal line may mean that the length of the specific signal line is substantially the same as the length of the normal signal line although not completely the same. That the length of the specific signal line is substantially the same as the length of the normal signal line may mean that a difference between the length of the specific signal line and the length of the normal signal line is within a selected (or predetermined) range.

The display panel according to embodiments of the disclosure may further comprise a common electrode disposed on the substrate.

The common electrode may include a plurality of first common electrode holes respectively positioned in the plurality of first transmissive areas. Each of the plurality of first common electrode holes may have a symmetrical shape with respect to a center line.

For example, the display area may further include a second optical area where light is transmitted, and the second optical area may include a plurality of emission areas and a plurality of second transmissive areas. In this case, in the second optical area, the substrate has no through-hole.

In this case, a common electrode disposed on the substrate may be further included, and the common electrode may include a plurality of second common electrode holes respectively positioned in the plurality of second transmissive areas.

Each of the plurality of second common electrode holes may have a symmetrical shape with respect to a center line.

As another example, the display area may further include a second optical area where light is transmitted, and the second optical area may include a through-hole of the substrate.

According to embodiments of the disclosure, there may be provided a display panel and a display device, in which an optical electronic device has a light transmission structure capable of normally receiving light (e.g., visible light, infrared light, or ultraviolet light), and the optical electronic device is not exposed to the front surface.

According to embodiments of the disclosure, there may be provided a display panel and a display device having a line characteristic deviation reduction structure between an optical area where light may be transmitted and a normal area where light is not transmitted. Accordingly, accurate display driving is possible and image quality may be enhanced. Further, a driving technique to reduce line characteristic deviation becomes unnecessary, allowing for high-efficiency driving and thus low-power design.

According to embodiments of the disclosure, there may be provided a display panel and a display device having a transmittance variation reduction structure in an optical area where light may be transmitted. Accordingly, the light transmission characteristics may be rendered uniform so that the operating performance (e.g., camera performance or detection performance) of the optical electronic device may be enhanced.

Technical benefits of the disclosure are not limited to the foregoing, and other unmentioned benefits would be apparent to one of ordinary skill in the art from the following description.

### BRIEF DESCRIPTION OF THE SEVERAL VIEWS OF THE DRAWINGS

The above and other objects, features, and advantages of the disclosure will be more clearly understood from the following detailed description, taken in conjunction with the accompanying drawings, in which:

FIGS. 1A, 1B, and 1C illustrate a display device according to embodiments of the disclosure;

FIG. 2 is a view illustrating a system configuration of a display device according to embodiments of the disclosure;

FIG. 3 is a view schematically illustrating a display panel according to embodiments of the disclosure;

FIG. 4 schematically illustrates a normal area, a first optical area, and a second optical area in a display panel according to embodiments of the disclosure;

FIG. 5 illustrates signal lines disposed on a display panel according to embodiments of the disclosure;

FIGS. 6 and 7 are plan views illustrating a first optical area in a display panel according to embodiments of the disclosure;

FIGS. 8 and 9 are views illustrating that common electrode holes are disposed in a first optical area of a display panel according to embodiments of the disclosure;

FIGS. 10, 11, and 12 are views illustrating that common electrode holes are disposed in a first optical area of a display panel according to embodiments of the disclosure;

FIGS. 13, 14, 15, 16, 17, and 18 are views illustrating that common electrode holes are disposed in a first optical area of a display panel according to embodiments of the disclosure;

FIGS. 19, 20, 21, 22, and 23 are views illustrating that common electrode holes are disposed in a first optical area of a display panel according to embodiments of the disclosure; and

FIGS. 24 and 25 are cross-sectional views illustrating a partial area in a first optical area of a display panel according to embodiments of the disclosure.

### DETAILED DESCRIPTION

Hereinafter, embodiments of the disclosure are described in detail with reference to the accompanying drawings. In assigning reference numerals to components of each drawing, the same components may be assigned the same numerals even when they are shown on different drawings. When determined to make the subject matter of the disclosure unclear, the detailed of the known art or functions may be skipped. As used herein, when a component “includes,” “has,” or “is composed of” another component, the component may add other components unless the component “only includes, has, or is composed of” the other component. As used herein, the singular forms “a,” “an” and “the” are intended to include the plural forms as well, unless the context clearly indicates otherwise.

Such denotations as “first,” “second,” “A,” “B,” “(a),” and “(b),” may be used in describing the components of the disclosure. These denotations are provided merely to distinguish a component from another, and the essence, order, or number of the components are not limited by the denotations.

In describing the positional relationship between components, when two or more components are described as “connected,” “coupled” or “linked,” the two or more components may be directly “connected,” “coupled” or “linked,” or another component may intervene. Here, the other component may be included in one or more of the two or more components that are “connected,” “coupled” or “linked” to each other.

When such terms as, e.g., “after,” “next to,” “after,” and “before,” are used to describe the temporal flow relationship related to components, operation methods, and fabricating methods, it may include a non-continuous relationship unless the term “immediately” or “directly” is used.

When a component is designated with a value or its corresponding information (e.g., level), the value or the corresponding information may be interpreted as including a tolerance that may arise due to various factors (e.g., process factors, internal or external impacts, or noise).

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Hereinafter, various embodiments of the disclosure are described in detail with reference to the accompanying drawings.

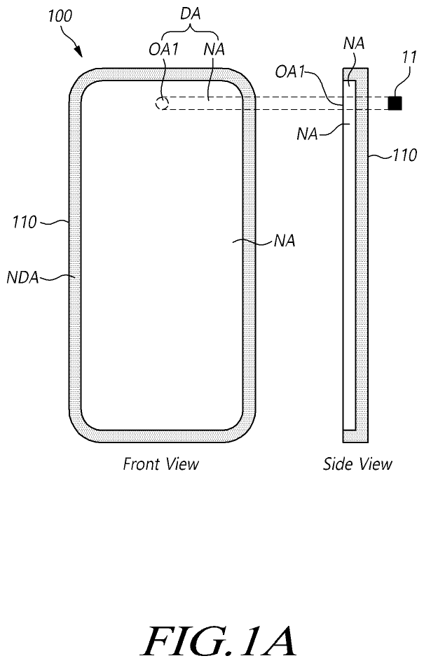

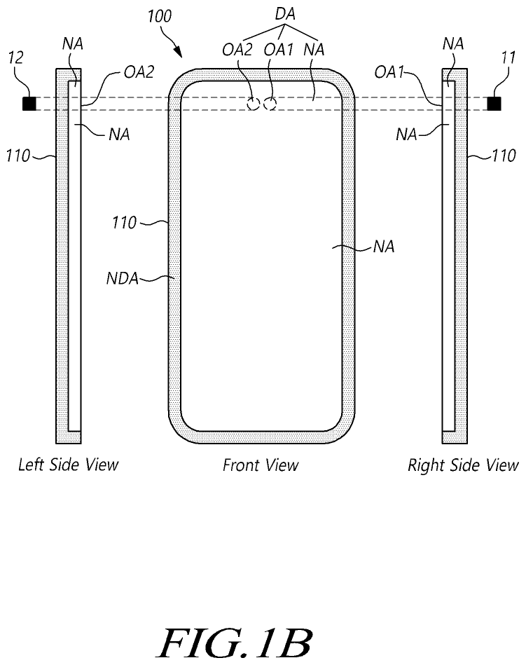

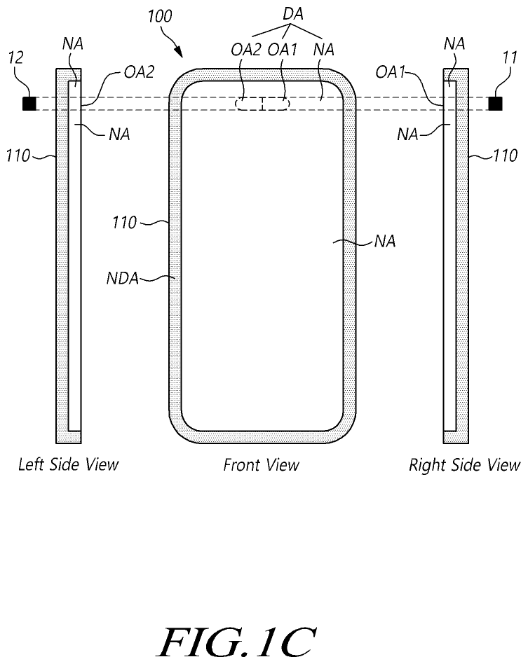

FIGS. 1A, 1B, and 1C illustrate a display device 100 according to embodiments of the disclosure.

Referring to FIGS. 1A, 1B, and 1C, a display device 100 according to embodiments of the disclosure may include a display panel 110 for displaying images and one or more optical electronic devices 11 and 12.

The display panel 110 may include a display area DA in which images are displayed and a non-display area NDA in which no image is displayed.

A plurality of subpixels may be disposed in the display area DA, and various signal lines for driving the plurality of subpixels may be disposed in the display area DA.

The non-display area NDA may be an area outside the display area DA. In the non-display area NDA, various signal lines may be disposed, and various driving circuits may be connected thereto. The non-display area NDA may be bent to be invisible from the front or may be covered by a case (not shown). The non-display area NDA is also referred to as a bezel or a bezel area.

In the display device 100 according to embodiments of the disclosure, one or more optical electronic devices 11 and 12 may be electronic components that are provided and installed separately from the display panel 110 and positioned under the display panel 110 (side opposite to the viewing surface).

In the display device 100 according to embodiments of the disclosure, one or more optical electronic devices 11 and 12 may be devices that may perform a selected (or predetermined) operation based on received light.

The one or more optical electronic devices 11 and 12 may be devices that receive the light transmitted through the display panel 110 and perform a selected (or predetermined) operation according to the received light. For example, the one or more optical electronic devices 11 and 12 may include one or more of a capture device, such as a camera (image sensor), and a detection sensor, such as a proximity sensor and an illuminance sensor. For example, the detection sensor may be an infrared sensor.

The light required for the operation of the one or more optical electronic devices 11 and 12 may enter the front surface (viewing surface) of the display panel 110 and pass through the display panel 110 to one or more optical electronic devices 11 and 12 positioned under the display panel 110 (side opposite to the viewing surface). For example, the light required for the operation of the one or more optical electronic devices 11 and 12 and passing through the display panel 110 may include one or more of visible light, infrared light, and ultraviolet light.

Referring to FIGS. 1A, 1B, and 1C, in the display panel 110 according to embodiments of the disclosure, the display area DA may include a normal area NA and one or more optical areas OA1 and OA2. The one or more optical areas OA1 and OA2 may be areas overlapping the one or more optical electronic devices 11 and 12.

According to the example of FIG. 1A, the display area DA may include the normal area NA and the first optical area OA1. The normal area NA may be positioned outside the first optical area OA1. At least a portion of the first optical area OA1 may overlap the first optical electronic device 11.

According to the example of FIG. 1B, the display area DA may include a normal area NA, a first optical area OA1, and a second optical area OA2. In the example of FIG. 1B, the normal area NA may be present between the first optical area OA1 and the second optical area OA2. At least a portion of the first optical area OA1 may overlap the first optical electronic device 11, and at least a portion of the second optical area OA2 may overlap the second optical electronic device 12.

According to the example of FIG. 1C, the display area DA may include a normal area NA, a first optical area OA1, and a second optical area OA2. In the example of FIG. 1C, the normal area NA is not present between the first optical area OA1 and the second optical area OA2. In other words, the first optical area OA1 and the second optical area OA2 contact each other. At least a portion of the first optical area OA1 may overlap the first optical electronic device 11, and at least a portion of the second optical area OA2 may overlap the second optical electronic device 12.

The one or more optical areas OA1 and OA2 should have both an image display structure and a light transmission structure. In other words, since the one or more optical areas OA1 and OA2 are partial areas of the display area DA, emission areas of subpixels for displaying images should be disposed in the one or more optical areas OA1 and OA2. A light transmission structure for transmitting light to the one or more optical electronic devices 11 and 12 should be formed in one or more optical areas OA1 and OA2.

The one or more optical electronic devices 11 and 12 are positioned behind (below, opposite to the viewing surface) the display panel 110 to receive the light transmitted through the display panel 110.

The one or more optical electronic devices 11 and 12 are not exposed on the front surface (viewing surface) of the display panel 110. Therefore, when the user looks at the front surface of the display device 110, the optical electronic devices 11 and 12 are not visible to the user.

For example, the first optical electronic device 11 may be a camera that receives light (visible light) of a visible light wavelength band, and the second optical electronic device 12 may be a detection sensor, such as a proximity sensor or an illuminance sensor. For example, the detection sensor may be an infrared sensor that detects light (infrared light) of an infrared light wavelength band. Conversely, the first optical electronic device 11 may be a detection sensor, and the second optical electronic device 12 may be a camera.

Hereinafter, for convenience of description, it is assumed that the first optical electronic device 11 is a camera and the second optical electronic device 12 is an infrared (IR)-based detection sensor. The camera may be a camera lens or an image sensor.

If the first optical electronic device 11 is a camera, the camera may be a front camera that is positioned behind (below) the display panel 110 but captures forward of the display panel 110. Accordingly, the user may capture (self-capture) through the camera invisible to the viewing surface while viewing the viewing surface of the display panel 110.

The normal area NA and one or more optical areas OA1 and OA2 included in the display area DA may be areas capable of displaying an image. However, the normal area NA may be an area where a light transmission structure is not required to be formed, and one or more optical areas OA1 and OA2 may be areas in which a light transmission structure is to be formed.

Accordingly, the one or more optical areas OA1 and OA2 should have a transmittance higher than or equal to a certain level, and the normal area NA may have no light transmittance or a lower transmittance less than the certain level.

For example, one or more optical areas OA1 and OA2 and the normal area NA may have different resolutions, subpixel placement structures, numbers of subpixels per unit area, electrode structures, line structures, electrode placement structures, or line placement structures.

For example, the number of subpixels per unit area in one or more optical areas OA1 and OA2 may be smaller than the number of subpixels per unit area in the normal area NA. In other words, the resolution of one or more optical areas OA1 and OA2 may be lower than the resolution of the normal area NA. Here, the number of subpixels per unit area may be meant to be equivalent to resolution, or pixel density, or pixel integration degree. For example, the unit for the number of subpixels per unit area may be pixels per inch (PPI), which means the number of pixels in one inch.

For example, the number of subpixels per unit area in the first optical area OA1 may be smaller than the number of subpixels per unit area in the normal area NA. The number of subpixels per unit area in the second optical area OA2 may be larger than or equal to the number of subpixels per unit area in the first optical area OA1 and be smaller than the number of subpixels per unit area in the normal area NA.

Meanwhile, as one method for increasing the transmittance of at least one of the first optical area OA1 and the second optical area OA2, a pixel density differential design scheme may be applied as described above. According to the pixel density differential design scheme, the display panel 110 may be designed so that the number of subpixels per unit area of at least one of the first optical area OA1 and the second optical area OA2 is larger than the number of subpixels per unit area of the normal area NA.

However, in some cases, as another method for increasing the transmittance of at least one of the first optical area OA1 and the second optical area OA2, a pixel size differential design scheme may be applied. According to the pixel size differential design scheme, the display panel 110 may be designed so that the number of subpixels per unit area of at least one of the first optical area OA1 and the second optical area OA2 is identical or similar to the number of subpixels per unit area of the normal area NA, and the size of each subpixel (i.e., the size of the emission area) disposed in at least one of the first optical area OA1 and the second optical area OA2 is smaller than the size of each subpixel SP (i.e., the size of the emission area) disposed in the normal area NA.

Hereinafter, for convenience of description, it is assumed in the following description that, of the two schemes (pixel density differential design scheme and pixel size differential design scheme) for increasing the transmittance of at least one of the first optical area OA1 and the second optical area OA2, the pixel density differential design scheme is applied. Accordingly, that the number of subpixels per unit area is small, as described below, may be an expression corresponding to the subpixel size being small, and that the number of subpixels per unit area is large may be an expression corresponding to the subpixel size being large.

The first optical area OA1 may have various shapes, such as a circle, an ellipse, a quadrangle, a hexagon, or an octagon. The second optical area OA2 may have various shapes, such as a circle, an ellipse, a square, a hexagon, or an octagon. The first optical area OA1 and the second optical area OA2 may have the same shape or different shapes.

Referring to FIG. 1C, when the first optical area OA1 and the second optical area OA2 contact, the entire optical area including the first optical area OA1 and the second optical area OA2 may have various shapes, such as a circle, an ellipse, a square, a hexagon, or an octagon. Hereinafter, for convenience of description, each of the first optical area OA1 and the second optical area OA2 is exemplified as having a circular shape.

In the display device 100 according to embodiments of the disclosure, if the first optical electronic device 11 that is not exposed to the outside and is hidden in a lower portion of the display panel 100 is a camera, the display device 100 according to embodiments of the disclosure may be referred to as a display to which under display camera (UDC) technology has been applied.

Accordingly, the display device 100 according to embodiments of the disclosure does not require a notch or camera hole for camera exposure to be formed in the display panel 110, thereby preventing a reduction in the display area DA. Thus, as there is no need to form a notch or camera hole for exposure of the camera in the display panel 110, the size of the bezel area may be reduced, and design restrictions may be freed, thereby increasing the degree of freedom in design.

In the display device 100 according to embodiments of the disclosure, although one or more optical electronic devices 11 and 12 are positioned to be hidden behind the display panel 110, one or more optical electronic devices 11 and 12 should be able to normally perform selected (or predetermined) functions by normally receiving light.

Further, in the display device 100 according to embodiments of the disclosure, although one or more optical electronic devices 11 and 12 are positioned to be hidden behind the display panel 110 and are positioned to overlap the display area DA, the one or more optical areas OA1 and OA2 overlapping the one or more optical electronic devices 11 and 12 in the display area DA should be capable of normal image display.

Since the above-mentioned first optical area OA1 is designed as a transmittable area, the image display characteristics in the first optical area OA1 may differ from the image display characteristics in the normal area NA.

Further, in designing the first optical area OA1 to enhance the image display characteristics, the transmittance of the first optical area OA1 may be degraded.

Accordingly, embodiments of the disclosure propose a structure of the first optical area OA1 capable of enhancing transmittance in the first optical area OA1 without causing an image quality deviation between the first optical area OA1 and the normal area NA.

Further, embodiments of the disclosure propose a structure of the second optical area OA2 capable of enhancing transmittance in the second optical area OA2 and image quality for the second optical area OA2, as well as for the first optical area OA1.

Further, in the display device 100 according to embodiments of the disclosure, the first optical area OA1 and the second optical area OA2 are similar in that they are light transmittable areas, but differ in use cases.

Therefore, in the display device 100 according to embodiments of the disclosure, the structure of the first optical area OA1 and the structure of the second optical area OA2 are basically similar or the same, but they may differ in, e.g., resolution, subpixel arrangement structure, number of subpixels in unit area, electrode structure, line structure, electrode arrangement structure, or line arrangement structure.

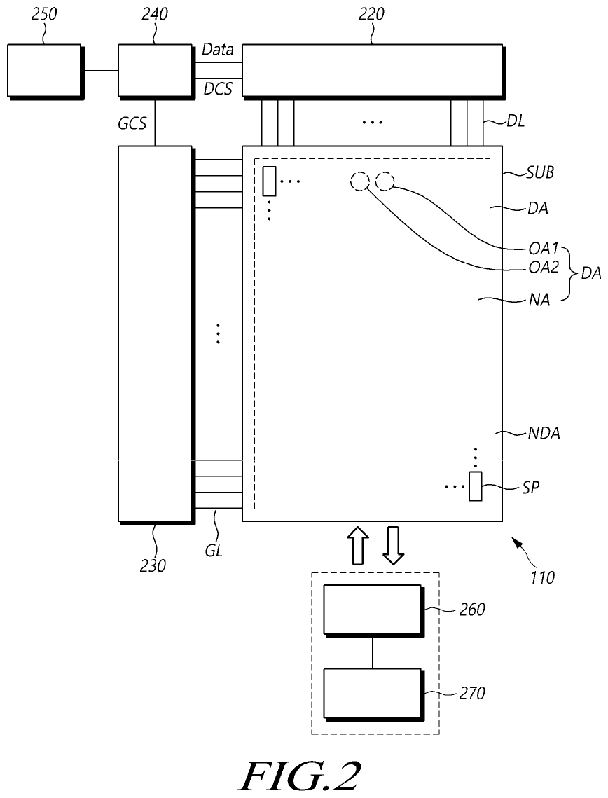

FIG. 2 is a view illustrating a system configuration of a display device 100 according to embodiments of the disclosure.

Referring to FIG. 2, a display device 100 may include a display panel 110 and display driving circuits, as components for displaying images. The display driving circuits are circuits for driving the display panel 110 and may include a data driving circuit 220, a gate driving circuit 230, and a display controller 240.

The display panel 110 may include a display area DA in which images are displayed and a non-display area NDA in which no image is displayed. The non-display area NDA may be an outer area of the display area DA and be referred to as a bezel area. The whole or part of the non-display area NDA may be an area visible from the front surface of the display device 100 or an area that is bent and not visible from the front surface of the display device 100.

The display panel 110 may include a substrate SUB and a plurality of subpixels SP disposed on the substrate SUB. The display panel 110 may further include various types of signal lines to drive the plurality of subpixels SP.

The display device 100 according to embodiments of the disclosure may be a liquid crystal display device or a self-emission display device in which the display panel 110 emits light by itself. When the display device 100 according to the embodiments of the disclosure is a self-emission display device, each of the plurality of subpixels SP may include a light emitting element. For example, the display device 100 according to embodiments of the disclosure may be an organic light emitting diode display in which the light emitting element is implemented as an organic light emitting diode (OLED). As another example, the display device 100 according to embodiments of the disclosure may be an inorganic light emitting display device in which the light emitting element is implemented as an inorganic material-based light emitting diode. As another example, the display device 100 according to embodiments of the disclosure may be a quantum dot display device in which the light emitting element is implemented as a quantum dot which is self-emission semiconductor crystal.

The structure of each of the plurality of subpixels SP may vary according to the type of the display device 100. For example, when the display device 100 is a self-emission display device in which the subpixels SP emit light by themselves, each subpixel SP may include a light emitting element that emits light by itself, one or more transistors, and one or more capacitors.

For example, various types of signal lines may include a plurality of data lines DL transferring data signals (also referred to as data voltages or image signals) and a plurality of gate lines GL transferring gate signals (also referred to as scan signals).

The plurality of data lines DL and the plurality of gate lines GL may cross each other. Each of the plurality of data lines DL may be disposed while extending in a first direction. Each of the plurality of gate lines GL may be disposed while extending in a second direction. Here, the first direction may be a column direction and the second direction may be a row direction. The first direction may be the row direction, and the second direction may be the column direction. For convenience of description, described below is an example in which each of the plurality of data lines DL is disposed in the column direction, and each of the plurality of gate lines GL is disposed in the row direction.

The data driving circuit 220 is a circuit for driving the plurality of data lines DL, and may output data signals to the plurality of data lines DL. The gate driving circuit 230 is a circuit for driving the plurality of gate lines GL, and may output gate signals to the plurality of gate lines GL.

The display controller 240 is a device for controlling the data driving circuit 220 and the gate driving circuit 230 and may control driving timings for the plurality of data lines DL and driving timings for the plurality of gate lines GL.

The display controller 240 may supply a data driving control signal DCS to the data driving circuit 220 to control the data driving circuit 220 and may supply a gate driving control signal GCS to the gate driving circuit 230 to control the gate driving circuit 230.

The display controller 240 may receive input image data from the host system 250 and supply image data Data to the data driving circuit 220 based on the input image data.

The data driving circuit 220 may receive digital image data Data from the display controller 240 and may convert the received image data Data into analog data signals and output the analog data signals to the plurality of data lines DL.

The gate driving circuit 230 may receive a first gate voltage corresponding to a turn-on level voltage and a second gate voltage corresponding to a turn-off level voltage, along with various gate driving control signals GCS, generate gate signals, and supply the generated gate signals to the plurality of gate lines GL.

For example, the data driving circuit 220 may be connected with the display panel 110 by a tape automated bonding (TAB) method or connected to a bonding pad of the display panel 110 by a chip on glass (COG) or chip on panel (COP) method or may be implemented by a chip on film (COF) method and connected with the display panel 110.

The gate driving circuit 230 may be connected with the display panel 110 by TAB method or connected to a bonding pad of the display panel 110 by a COG or COP method or may be connected with the display panel 110 according to a COF method. Alternatively, the gate driving circuit 230 may be formed in a gate in panel (GIP) type, in the non-display area NDA of the display panel 110. The gate driving circuit 230 may be disposed on the substrate or may be connected to the substrate. In other words, the gate driving circuit 230 that is of a GIP type may be disposed in the non-display area NDA of the substrate. The gate driving circuit 230 that is of a chip-on-glass (COG) type or chip-on-film (COF) type may be connected to the substrate.

Meanwhile, at least one of the data driving circuit 220 and the gate driving circuit 230 may be disposed in the display area DA of the display panel 110. For example, at least one of the data driving circuit 220 and the gate driving circuit 230 may be disposed not to overlap the subpixels SP or to overlap all or some of the subpixels SP.

The data driving circuit 220 may be connected to one side (e.g., an upper or lower side) of the display panel 110. Depending on the driving scheme or the display panel design scheme, data driving circuits 220 may be connected with both the sides (e.g., both the upper and lower sides) of the display panel 110, or two or more of the four sides of the display panel 110.

The gate driving circuit 230 may be connected to one side (e.g., a left or right side) of the display panel 110. Depending on the driving scheme or the display panel design scheme, gate driving circuits 230 may be connected with both the sides (e.g., both the left and right sides) of the display panel 110, or two or more of the four sides of the display panel 110.

The display controller 240 may be implemented as a separate component from the data driving circuit 220, or the display controller 140 and the data driving circuit 220 may be integrated into an integrated circuit (IC).

The display controller 240 may be a timing controller used in typical display technology, a control device that may perform other control functions as well as the functions of the timing controller, or a control device other than the timing controller, or may be a circuit in the control device. The display controller 240 may be implemented as various circuits or electronic components, such as an integrated circuit (IC), a field programmable gate array (FPGA), an application specific integrated circuit (ASIC), or a processor.

The display controller 240 may be mounted on a printed circuit board or a flexible printed circuit and may be electrically connected with the data driving circuit 220 and the gate driving circuit 230 through the printed circuit board or the flexible printed circuit.

The display controller 240 may transmit/receive signals to/from the data driving circuit 220 according to one or more selected (or predetermined) interfaces. The interface may include, e.g., a low voltage differential signaling (LVDS) interface, an embedded clock point-point interface (EPI) interface, and a serial peripheral interface (SPI).

To provide a touch sensing function as well as an image display function, the display device 100 according to embodiments of the disclosure may include a touch sensor and a touch sensing circuit that senses the touch sensor to detect whether a touch occurs by a touch object, such as a finger or pen, or the position of the touch.

The touch sensing circuit may include a touch driving circuit 260 that drives and senses the touch sensor and generates and outputs touch sensing data and a touch controller 270 that may detect an occurrence of a touch or the position of the touch using touch sensing data.

The touch sensor may include a plurality of touch electrodes. The touch sensor may further include a plurality of touch lines for electrically connecting the plurality of touch electrodes and the touch driving circuit 260.

The touch sensor may be present in a touch panel form outside the display panel 110 or may be present inside the display panel 110. When the touch sensor, in the form of a touch panel, exists outside the display panel 110, the touch sensor is referred to as an external type. When the touch sensor is of the external type, the touch panel and the display panel 110 may be separately manufactured or may be combined during an assembly process. The external-type touch panel may include a touch panel substrate and a plurality of touch electrodes on the touch panel substrate.

When the touch sensor is present inside the display panel 110, the touch sensor may be formed on the substrate SUB, together with signal lines and electrodes related to display driving, during the manufacturing process of the display panel 110.

The touch driving circuit 260 may supply a touch driving signal to at least one of the plurality of touch electrodes and may sense at least one of the plurality of touch electrodes to generate touch sensing data.

The touch sensing circuit may perform touch sensing in a self-capacitance sensing scheme or a mutual-capacitance sensing scheme.

When the touch sensing circuit performs touch sensing in the self-capacitance sensing scheme, the touch sensing circuit may perform touch sensing based on capacitance between each touch electrode and the touch object (e.g., finger or pen). According to the self-capacitance sensing scheme, each of the plurality of touch electrodes may serve both as a driving touch electrode and as a sensing touch electrode. The touch driving circuit 260 may drive all or some of the plurality of touch electrodes and sense all or some of the plurality of touch electrodes.

When the touch sensing circuit performs touch sensing in the mutual-capacitance sensing scheme, the touch sensing circuit may perform touch sensing based on capacitance between the touch electrodes. According to the mutual-capacitance sensing scheme, the plurality of touch electrodes are divided into driving touch electrodes and sensing touch electrodes. The touch driving circuit 260 may drive the driving touch electrodes and sense the sensing touch electrodes.

The touch driving circuit 260 and the touch controller 270 included in the touch sensing circuit may be implemented as separate devices or as a single device. The touch driving circuit 260 and the data driving circuit 220 may be implemented as separate devices or as a single device.

The display device 100 may further include a power supply circuit for supplying various types of power to the display driver integrated circuit and/or the touch sensing circuit.

The display device 100 according to embodiments of the disclosure may be a mobile terminal, such as a smart phone or a tablet, or a monitor or television (TV) in various sizes but, without limited thereto, may be a display in various types and various sizes capable of displaying information or images.

As described above, the display area DA in the display panel 110 may include the normal area NA and one or more optical areas OA1 and OA2. The normal area NA and one or more optical areas OA1 and OA2 are areas capable of displaying an image. However, the normal area NA is an area where a light transmission structure is not required to be formed, and one or more optical areas OA1 and OA2 are areas in which a light transmission structure is to be formed.

As described above, the display area DA in the display panel 110 may include one or more optical areas OA1 and OA2 together with the normal area NA, but for convenience of description, it is assumed that the display area DA includes both the first optical area OA1 and the second optical area OA2 (FIGS. 1B and 1C).

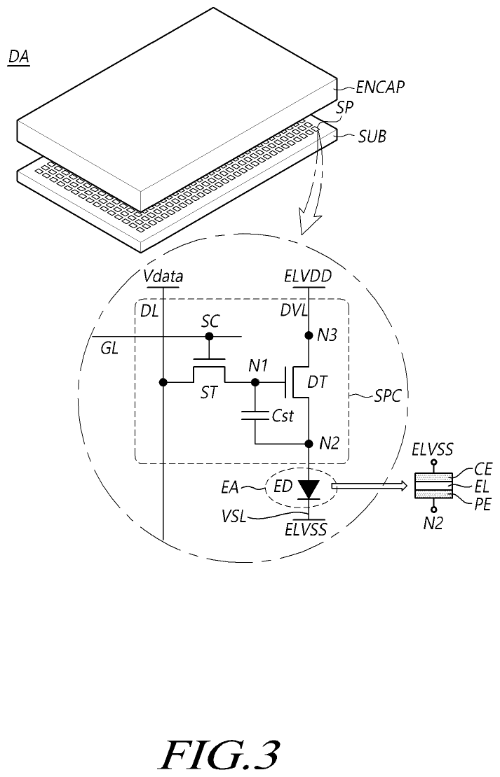

FIG. 3 is a view schematically illustrating a display panel 110 according to embodiments of the disclosure.

Referring to FIG. 3, a plurality of subpixels SP may be disposed in the display area DA of the display panel 110. The plurality of subpixels SP may be disposed in the normal area NA and the first optical area OA1 and the second optical area OA2 included in the display area DA.

Referring to FIG. 3, each of the plurality of subpixels SP may include a light emitting element ED and a subpixel circuit unit SPC configured to drive the light emitting element ED.

Referring to FIG. 3, the subpixel circuit unit SPC may include a driving transistor DT for driving the light emitting element ED, a scan transistor ST for transferring the data voltage Vdata to the first node N1 of the driving transistor DT, and a storage capacitor Cst for maintaining a constant voltage during one frame.

The driving transistor DT may include the first node N1 to which the data voltage may be applied, a second node N2 electrically connected with the light emitting element ED, and a third node N3 to which a driving voltage ELVDD is applied from a driving voltage line DVL. The first node N1 in the driving transistor DT may be a gate node, the second node N2 may be a source node or a drain node, and the third node N3 may be the drain node or the source node. For convenience of description, described below is an example in which the first node N1 in the driving transistor DT is a gate node, the second node N2 is a source node, and the third node N3 is a drain node.

The light emitting element ED may include a pixel electrode PE, a light emitting layer EL, and a common electrode CE. The pixel electrode PE may be an electrode disposed in each subpixel SP, and the common electrode CE may be an electrode commonly disposed in all the subpixels SP.

For example, a base voltage ELVSS corresponding to a common voltage may be applied to the common electrode CE. In this case, the common electrode CE may receive the base voltage ELVSS through the base voltage line VSL. The pixel electrode PE may be electrically connected to the second node N2 of the driving transistor DT of each subpixel SP.

For example, the pixel electrode PE may be an anode, and the common electrode CE may be a cathode. Conversely, the pixel electrode PE may be a cathode, and the common electrode CE may be an anode. For convenience of description, it is assumed below that the pixel electrode PE is an anode, and the common electrode CE is a cathode.

Each light emitting element ED may include portions where the pixel electrode PE, the light emitting layer EL, and the common electrode CE overlap. Each light emitting element ED may have a selected (or predetermined) emission area EA. The emission area EA of each light emitting element ED may be defined as an area where the pixel electrode PE, the light emitting layer EL, and the common electrode CE overlap.

For example, the light emitting element ED may be an organic light emitting diode (OLED), an inorganic light emitting diode (LED), or a quantum dot light emitting element. For example, when the light emitting element ED is an organic light emitting diode (OLED), the light emitting layer EL of the light emitting element ED may include an organic light emitting layer EL including an organic material.

The scan transistor ST may be on/off controlled by a scan signal SC, which is a gate signal, applied via the gate line GL and be electrically connected between the first node N1 of the driving transistor DT and the data line DL.

The storage capacitor Cst may be electrically connected between the first node N1 and second node N2 of the driving transistor DT.

The subpixel circuit unit SPC may have a 2T (transistor) 1C (capacitor) structure which includes two transistors DT and ST and one capacitor Cst as shown in FIG. 3 and, in some cases, each subpixel SP may further include one or more transistors or one or more capacitors. For example, the subpixel circuit unit SPC may have a 7T1C structure including 7 transistors and 1 capacitor Cst.

The capacitor Cst may be an external capacitor intentionally designed to be outside the driving transistor DT, but not a parasite capacitor (e.g., Cgs or Cgd) which is an internal capacitor that may be present between the first node N1 and the second node N2 of the driving transistor DT. Each of the driving transistor DT and the scan transistor ST may be an n-type transistor or a p-type transistor.

Since the circuit elements (particularly, the light emitting element ED implemented as an organic light emitting diode (OLED) containing an organic material) in each subpixel SP are vulnerable to external moisture or oxygen, an encapsulation layer ENCAP may be disposed on the display panel 110 to prevent penetration of external moisture or oxygen into the circuit elements (particularly, the light emitting element ED). The encapsulation layer ENCAP may be disposed to cover the light emitting elements ED.

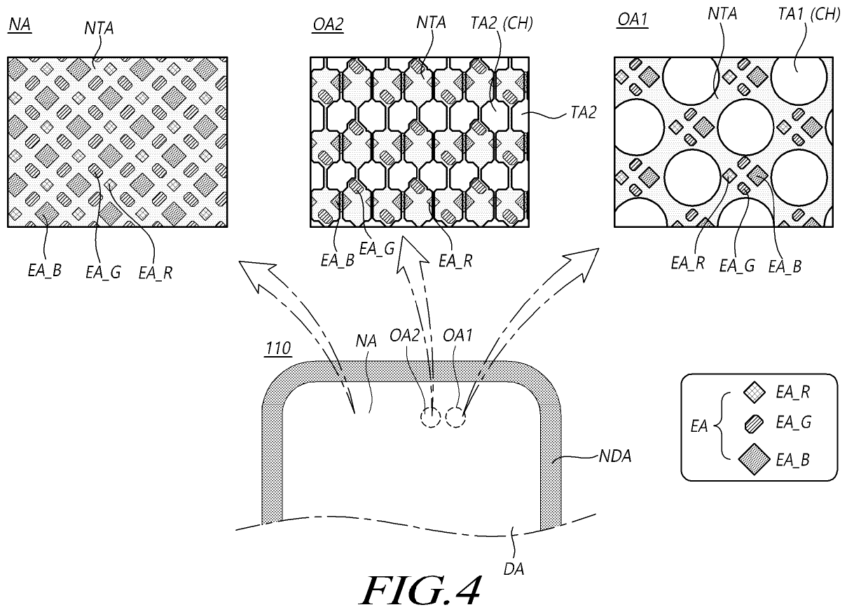

FIG. 4 schematically illustrates a normal area NA, a first optical area OA1, and a second optical area OA2 in a display panel according to embodiments of the disclosure.

Referring to FIG. 4, the display panel 110 according to embodiments of the disclosure may include a display area DA in which images are displayed and a non-display area NDA in which no image is displayed. The display area DA may include a first optical area OA1, a second optical area OA2, and a normal area NA.

Since the first optical area OA1, the second optical area OA2, and the normal area NA are included in the display area DA, it may have a display structure. For example, each of the first optical area OA1, the second optical area OA2, and the normal area NA may include a plurality of emission areas EA.

Further, the first optical area OA1 and the second optical area OA2 may be areas capable of light transmission, and the normal area NA may be an area in which light transmission is impossible or light transmission is insignificant. The normal area NA may mean an area where light may not be transmitted, other than the first optical area OA1 and the second optical area OA2. Here, the transmission of light may mean that light passes between the front surface and the rear surface of the display panel 110.

The first optical area OA1 may be an area overlapping the first optical electronic device 11. The second optical area OA2 may be an area overlapping the second optical electronic device 12.

Each of the first optical area OA1 and the second optical area OA2 may have a light transmission structure. However, the first optical area OA1 and the second optical area OA2 may have different structural characteristics. For example, the transmittance of the first optical area OA1 may be higher than the transmittance of the second optical area OA2. The resolution or the number of subpixels per unit area of the first optical area OA1 may be lower than the resolution or the number of subpixels per unit area of the second optical area OA2.

The first optical electronic device 11 may perform a selected (or predetermined) operation using light of a first wavelength band of light transmitted through the first optical area OA1. The second optical electronic device 12 may perform a selected (or predetermined) operation using light of a second wavelength band different from the first wavelength band of light transmitted through the second optical area OA2.

The first wavelength band may include one or more of a wavelength band of visible light, a wavelength band of infrared light, and a wavelength band of ultraviolet light. The second wavelength band may include one or more of a wavelength band of visible light, a wavelength band of infrared light, and a wavelength band of ultraviolet light, but may be different from the first wavelength band.

For example, the first optical electronic device 11 may be a camera and the second optical electronic device 12 may be a detection sensor. The first optical electronic device 11 may perform a camera operation using light of a visible wavelength band corresponding to a first wavelength band of light transmitted through the first optical area OA1. The second optical electronic device 12 may perform a detection operation using light of an infrared wavelength band corresponding to the second wavelength band of light transmitted through the second optical area OA2.

Referring to FIG. 4, each of the first optical area OA1 and the second optical area OA2 may be circular or octagonal. However, the disclosure is not limited thereto, and each of the first optical area OA1 and the second optical area OA2 may have various shapes such as an elliptical shape, a polygonal shape, or an irregular shape.

The first optical area OA1 and the second optical area OA2 may have the same shape. Alternatively, the first optical area OA1 and the second optical area OA2 may have different shapes.

Referring to FIG. 4, the display area DA may include a plurality of emission areas EA. Since the normal area NA, the first optical area OA1, and the second optical area OA2 are areas included in the display area DA, each of the normal area NA, the first optical area OA1, and the second optical area OA2 may include a plurality of emission areas EA.

The plurality of emission areas EA may include emission areas emitting light of three or more colors. For example, the plurality of emission areas EA may include a first color emission area emitting first color light, a second color emission area emitting second color light, and a third color emission area emitting third color light.

For example, when the first color light is red light, the second color light is green light, and the third color light is blue light, the first color emission area may be referred to as a red emission area EA_R, the second color emission area may be referred to as a green emission area EA_G and the third color emission area may be referred to as a blue emission area EA_B.

The red emission area EA_R, the green emission area EA_G, and the blue emission area EA_B may have the same size (emission area size). Alternatively, at least one of the red emission area EA_R, the green emission area EA_G, and the blue emission area EA_B may have a size (emission area size) different from the rest.

As mentioned above, the first color, the second color, and the third color are different colors and may be various colors. For example, the first color, the second color, and the third color may include red, green, and blue. Hereinafter, for convenience of description, a case in which the first color is red, the second color is green, and the third color is blue is exemplified. However, it is not limited thereto.

When the first color is red, the second color is green, and the third color is blue, the size (emission area size) of the blue emission area EA_B may be the largest among the size (emission area size) of the red emission area EA_R, the size (emission area size) of the green emission area EA_G, and the size (emission area size) of the blue emission area EA_B.

The light emitting element ED disposed in the red emission area EA_R may include a light emitting layer EL emitting red light. The light emitting element ED disposed in the green emission area EA_G may include a light emitting layer EL emitting green light. The light emitting element ED disposed in the blue emission area EA_B may include a light emitting layer EL emitting blue light.

Among the light emitting layer EL emitting red light, the light emitting layer EL emitting green light, and the light emitting layer EL emitting blue light, an organic material included in the light emitting layer EL emitting blue light may be most easily deteriorated. Thus, as the size of the blue emission area EA_B is designed to be the largest, the density of the current supplied to the light emitting element ED disposed in the blue emission area EA_B may be the smallest. Accordingly, the degree of deterioration of the light emitting element ED disposed in the blue emission area EA_B may be similar to the degree of deterioration of the light emitting element ED disposed in the red emission area EA_R and the degree of deterioration of the light emitting element ED disposed in the green emission area EA_G.

Accordingly, the deterioration deviations between the light emitting element ED disposed in the red emission area EA_R, the light emitting element ED disposed in the green emission area EA_G, and the light emitting element ED disposed in the blue emission area EA_B may be removed or reduced, thereby improving image quality.

Referring to FIG. 4, each of the plurality of first transmissive areas TA1 included in the first optical area OA1 may have various shapes such as an elliptical shape, a polygonal shape, or an irregular shape. Each of the second transmissive areas TA2 included in the second optical area OA2 may have various shapes such as an elliptical shape, a polygonal shape, or an irregular shape.

The plurality of first transmissive areas TA1 may have the same shape. Alternatively, some of the plurality of first transmissive areas TA1 may have a different shape from the rest. The plurality of second transmissive areas TA2 may have the same shape. Alternatively, some of the plurality of second transmissive areas TA2 may have a different shape from the rest.

The first transmissive area TA1 and the second transmissive area TA2 may have the same shape. Alternatively, the first transmissive area TA1 and the second transmissive area TA2 may have different shapes.

Referring to FIG. 4, the entire normal area NA may correspond to a non-transmissive area. In other words, the normal area NA may include a non-transmissive area NTA including a plurality of emission areas EA. In other words, the entire normal area NA may be the non-transmissive area NTA, and the normal area NA may not include the transmissive area TA.

The first optical area OA1 may further include a non-transmissive area NTA including a plurality of emission areas EA and a plurality of first transmissive areas TA1. The non-transmissive area NTA included in the first optical area OA1 may be an area through which light is not transmitted at all, or may be an area through which light is transmitted with a transmittance lower than that of the first transmissive area TA1.

The second optical area OA2 may further include a non-transmissive area NTA including a plurality of emission areas EA and a plurality of second transmissive areas TA2. The non-transmissive area NTA included in the second optical area OA2 may be an area through which light is not transmitted at all, or may be an area through which light is transmitted with a transmittance lower than that of the second transmissive area TA2.

Meanwhile, the common electrode CE may include a plurality of common electrode holes CH corresponding to a plurality of openings. The plurality of common electrode holes CH may be formed in the first optical area OA1 and the second optical area OA2. In other words, the positions where the plurality of common electrode holes CH are formed may be the first optical area OA1 and the second optical area OA2.

Referring to FIG. 4, the positions where the plurality of common electrode holes CH are formed in the common electrode CE may correspond to the plurality of first transmissive areas TA1, respectively, included in the first optical area OA1. Further, the positions where the plurality of common electrode holes CH are formed in the common electrode CE may correspond to the plurality of second transmissive areas TA2, respectively, included in the second optical area OA2. Accordingly, the transmittance of each of the first optical area OA1 and the second optical area OA2 may be enhanced.

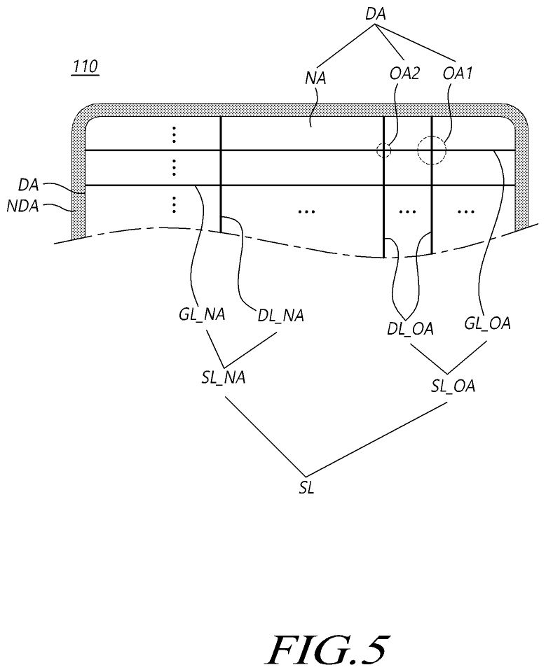

FIG. 5 illustrates signal lines SL disposed on a display panel 110 according to embodiments of the disclosure.

Referring to FIG. 5, the display panel 110 according to embodiments of the disclosure may include a plurality of subpixels SP and a plurality of signal lines SL for driving the plurality of subpixels SP.

Referring to FIG. 5, each of the plurality of subpixels SP may include a light emitting element ED and a subpixel circuit SPC for driving the light emitting element ED. The emission area EA may be formed by the light emitting element ED.

Referring to FIG. 5, the plurality of signal lines SL may supply various driving signals required to drive the plurality of subpixels SP to the plurality of subpixels SP.

For example, various driving signals may include a data signal Vdata for driving the data line DL, a scan signal SC for driving the gate line GL, and the like. The various driving signals may further include a driving voltage ELVDD for driving the driving voltage line DVL and a base voltage ELVSS for driving the base voltage line VSL connected to the common electrode CE.

Accordingly, the plurality of signal lines may include a plurality of data lines DL for supplying data signals Vdata and a plurality of gate lines GL for supplying gate signals such as scan signals SC. The plurality of signal lines may further include a driving voltage line DVL for supplying the driving voltage ELVDD and a base voltage line VSL for supplying the base voltage ELVSS.

Referring to FIG. 5, the display area DA may include a normal area NA, a first optical area OA1, and a second optical area OA2.

Referring to FIG. 5, each of the normal area NA, the first optical area OA1, and the second optical area OA2 may include a plurality of emission areas EA. A plurality of light emitting elements ED and a plurality of subpixel circuits SPC may be disposed in each of the normal area NA, the first optical area OA1, and the second optical area OA2.

Referring to FIG. 5, the plurality of signal lines SL may include a plurality of normal signal lines SL_NA and a plurality of specific signal lines SL_OA.

The plurality of normal signal lines SL_NA may be signal lines disposed only in the normal area NA without passing through the first optical area OA1 and the second optical area OA2.

The plurality of specific signal lines SL_OA may be signal lines passing through at least one of the first optical area OA1 and the second optical area OA2.

For example, the plurality of normal signal lines SL_NA may include a plurality of data lines DL_NA and a plurality of gate lines GL_NA that do not pass through the first optical area OA1 and the second optical area OA2.

For example, the plurality of specific signal lines SL_OA may include a plurality of data lines DL_OA and a plurality of gate lines GL_OA passing through at least one of the first optical area OA1 and the second optical area OA2.

As described above, as the plurality of specific signal lines SL_OA pass through at least one of the first optical area OA1 and the second optical area OA2, the transmission characteristics of the first optical area OA1 and the second optical area OA2 may be affected by the plurality of specific signal lines SL_OA.

Meanwhile, the positions where the plurality of common electrode holes CH are formed in the common electrode CE may correspond to the plurality of first transmissive areas TA1, respectively, included in the first optical area OA1. Further, the positions where the plurality of common electrode holes CH are formed in the common electrode CE may correspond to the plurality of second transmissive areas TA2, respectively, included in the second optical area OA2. Accordingly, the transmittance of each of the first optical area OA1 and the second optical area OA2 may be enhanced.

In order to further increase the transmittance of the first optical area OA1, when the plurality of specific signal lines SL_OA pass through the first optical area OA1, the plurality of specific signal lines SL_OA may be disposed to bypass the plurality of common electrode holes CH corresponding to the plurality of first transmissive areas TAL. Similarly, in order to further increase the transmittance of the second optical area OA2, when the plurality of specific signal lines SL_OA pass through the second optical area OA2, the plurality of specific signal lines SL_OA may be disposed to bypass the plurality of common electrode holes CH corresponding to the plurality of second transmissive areas TA2.

In this case, the plurality of specific signal lines SL_OA passing through at least one of the first optical area OA1 and the second optical area OA2 may have a line length longer than the plurality of normal signal lines SL_NA not passing through the first optical area OA1 and the second optical area OA2.

Accordingly, the plurality of specific signal lines SL_OA and the plurality of normal signal lines SL_NA may have different electrical characteristics (e.g., different line resistances, different signal transmission delays, etc.). As a result, driving characteristics between the subpixels SP connected to the plurality of specific signal lines SL_OA and the subpixels SP connected to the plurality of normal signal lines SL_NA may be varied, and image quality may deteriorate.

Meanwhile, when manufacturing the display panel 110, a process for patterning the common electrode CE having a plurality of common electrode holes CH may be performed. In this case, when a variation in the patterning process of the common electrode CE occurs, a variation in the transmittance of the plurality of common electrode holes CH of the common electrode CE may occur, and a transmittance deviation between the plurality of common electrode holes CH may also occur.

Accordingly, the display panel 110 according to embodiments of the disclosure may have a line characteristic deviation reduction structure.

According to the line characteristic deviation reduction structure according to embodiments of the disclosure, the electrical characteristic deviation (e.g., line resistance deviation, signal transmission delay deviation, etc.) between the plurality of specific signal lines SL_OA passing through at least one of the first optical area OA1 and the second optical area OA2 and the plurality of normal signal lines SL_NA not passing through the first optical area OA1 and the second optical area OA2 may be reduced.

Further, the display panel 110 according to embodiments of the disclosure may have a transmittance variation range reduction structure.

According to the transmittance variation range reduction structure according to embodiments of the disclosure, the transmittance variation range between the plurality of common electrode holes CH may be reduced even if a process variation occurs. Here, the plurality of common electrode holes CH may correspond to the plurality of first transmissive areas TA1, respectively, in the first optical area OA1, or may correspond to the plurality of second transmissive areas TA2, respectively, in the second optical area OA2.

Hereinafter, a line characteristic deviation reduction structure and a transmittance variation range reduction structure of the display panel 110 according to embodiments of the disclosure are described with reference to various exemplary drawings. However, for convenience of description, the first optical area OA1 of the first optical area OA1 and the second optical area OA2 is exemplified.

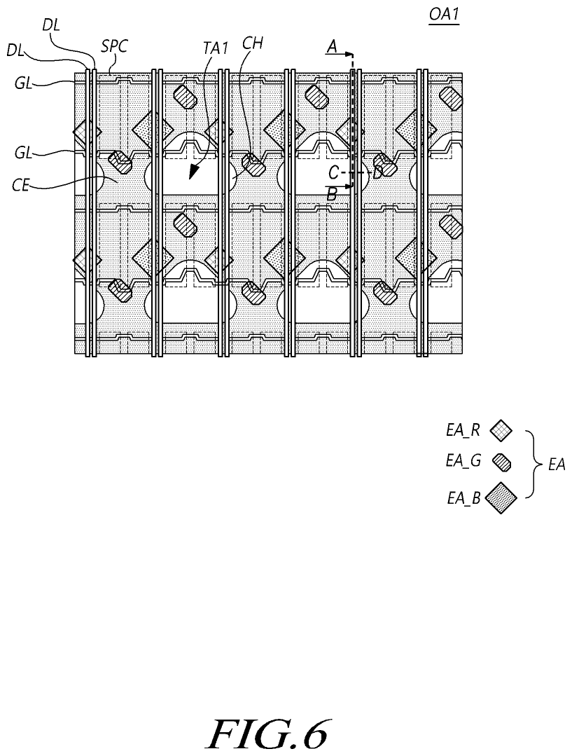

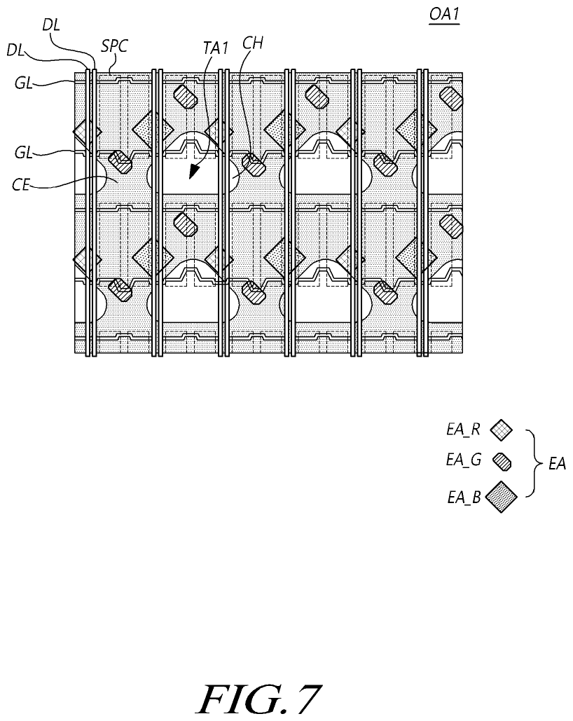

FIGS. 6 and 7 are plan views illustrating a first optical area OA1 of a display panel 110 according to embodiments of the disclosure.

The display panel 110 according to embodiments of the disclosure may include a substrate SUB including a display area DA in which an image is displayed, a plurality of signal lines SL disposed on the substrate SUB, and a common electrode CE disposed on the substrate SUB.

The display area DA may include a first optical area OA1 where light is transmitted and a normal area NA positioned outside the first optical area OA1. The normal area NA may include a plurality of emission areas EA.

The first optical area OA1 may include a plurality of first transmissive areas TA1 and a non-transmissive area NTA other than the plurality of first transmissive areas TAL.

The non-transmissive area NTA included in the first optical area OA1 may include a plurality of emission areas EA formed by the plurality of light emitting elements ED. Further, a plurality of subpixel circuits SPC may be disposed in the non-transmissive area NTA included in the first optical area OA1.

The common electrode CE may include a plurality of common electrode holes CH. The positions where the plurality of common electrode holes CH are formed may be the first optical area OA1. In other words, the plurality of common electrode holes CH may be present in the first optical area OA1. Accordingly, the plurality of common electrode holes CH may overlap with the first optical area OA1 when seen from a plan view.

The plurality of common electrode holes CH may be positioned to correspond to the plurality of first transmissive areas TA1, respectively.

As described above, the plurality of signal lines SL may include a plurality of normal signal lines SL_NA that do not pass through the first optical area OA1 and a plurality of specific signal lines SL_OA that pass through the first optical area OA1.

For example, the plurality of specific signal lines SL_OA passing through the first optical area OA1 may include the plurality of data lines DL. The plurality of specific signal lines SL_OA passing through the first optical area OA1 may include a plurality of gate lines GL.

According to the line characteristic deviation reduction structure of the display panel 110 according to embodiments of the disclosure, each of the plurality of specific signal lines SL_OA passing through the first optical area OA1 may be disposed across at least one of the plurality of first transmissive areas TA1 without bypassing the plurality of first transmissive areas TAL. In other words, each of the plurality of specific signal lines SL_OA may pass through at least one of the plurality of first transmissive areas TAL.

According to the line characteristic deviation reduction structure of the display panel 110 according to embodiments of the disclosure, each of the plurality of common electrode holes CH may overlap at least one of the plurality of specific signal lines SL_OA passing through the first optical area OA1.

According to the examples of FIGS. 6 and 7, the plurality of specific signal lines SL_OA may include a plurality of data lines DL passing through the first optical area OA1 in the column direction. Each of the plurality of data lines DL may be disposed across at least one of the plurality of first transmissive areas TA1 without bypassing the plurality of first transmissive areas TAL. Each of a plurality of common electrode holes CH may overlap four data lines DL. In other words, the four data lines DL may pass through one first transmissive area TA1 corresponding to one common electrode hole CH.

According to the line characteristic deviation reduction structure of the display panel 110 according to embodiments of the disclosure, the electrical characteristic deviation (e.g., line resistance deviation, signal transmission delay deviation, etc.) between the plurality of specific signal lines SL_OA passing through the first optical area OA1 and the plurality of normal signal lines SL_NA disposed only in the normal area NA without passing through the first optical area OA1 may be reduced.

FIG. 6 illustrates a case in which the plurality of common electrode holes CH of the common electrode CE are formed without a process variation, and FIG. 7 illustrates a case in which the plurality of common electrode holes CH of the common electrode CE are shifted to the right by a process variation.

Referring to FIG. 6, when there is no process variation, each common electrode hole CH may overlap four data lines DL. In other words, when there is no process variation, the four data lines DL may pass through one first transmissive area TA1 corresponding to one common electrode hole CH.

Referring to FIG. 6, when there is no process variation, the two data lines DL positioned on the left side and the two data lines DL positioned on the right side may be symmetrically arranged with respect to the column-wise center line of one common electrode hole CH. In other words, when there is no process variation, the two data lines DL positioned on the left side and the two data lines DL positioned on the right side may be arranged in a balanced manner with respect to the column-wise center line of one common electrode hole CH. Accordingly, when there is no process variation, the size of the overlapping area between the two data lines DL positioned on the left side and the common electrode hole CH and the size of the overlapping area between the two data lines DL on the right side and the common electrode hole CH may be the same.

Referring to FIG. 7, even when there is a process variation, each common electrode hole CH may overlap four data lines DL. In other words, even when there is a process variation, the four data lines DL may pass through one first transmissive area TA1 corresponding to one common electrode hole CH.

Referring to FIG. 7, when there is a process variation, the two data lines DL positioned on the left side and the two data lines DL positioned on the right side may be asymmetrically arranged with respect to the column-wise center line of one common electrode hole CH. In other words, when there is a process variation, the two data lines DL positioned on the left side and the two data lines DL positioned on the right side may be arranged in an unbalanced manner with respect to the column-wise center line of one common electrode hole CH. Accordingly, when there is a process variation, the size of the overlapping area between the two data lines DL positioned on the left side and the common electrode hole CH and the size of the overlapping area between the two data lines DL on the right side and the common electrode hole CH may be different from each other.

Each of the plurality of common electrode holes CH illustrated in FIGS. 6 and 7 may be triangular. This is merely an example, and the common electrode hole CH may have other various shapes.

A line characteristic deviation reduction structure and a transmittance variation range reduction structure of the display panel 110 according to embodiments of the disclosure are as follows.

In the display panel 110 according to embodiments of the disclosure, the plurality of signal lines SL may include a normal signal line SL_NA that does not pass through the first optical area OA1 and the second optical area OA2, and a specific signal line SL_OA that passes through at least one of the first optical area OA1 and the second optical area OA2.

Each of a plurality of specific signal lines SL_OA may be disposed parallel to the normal signal line SL_NA.

Each of a plurality of specific signal lines SL_OA may overlap at least one of a plurality of common electrode holes CH.

Each of the plurality of specific signal lines SL_OA may pass through at least one of the plurality of first transmissive areas TA1 and the plurality of second transmissive areas TA2. In other words, each of the plurality of specific signal lines SL_OA may be disposed across at least one of the plurality of first transmissive areas TA1 and the plurality of second transmissive areas TA2.

The specific signal line SL_OA may have the same length as the normal signal line SL_NA.

Each of the plurality of common electrode holes CH formed in the common electrode CE may have a symmetrical shape with respect to the center line. Here, the center line may include at least one of a column-wise center line and a row-wise center line.

According to the line characteristic deviation reduction structure and the transmittance variation range reduction structure according to embodiments of the disclosure, even if a process variation occurs, an electrical characteristic deviation (e.g., line resistance deviation, signal transmission delay deviation, etc.) between the plurality of specific signal lines SL_OA passing through at least one of the first optical area OA1 and the second optical area OA2 and the plurality of normal signal lines SL_NA not passing through the first optical area OA1 and the second optical area OA2 may be reduced, and a transmittance variation range between the plurality of common electrode holes CH may be reduced.

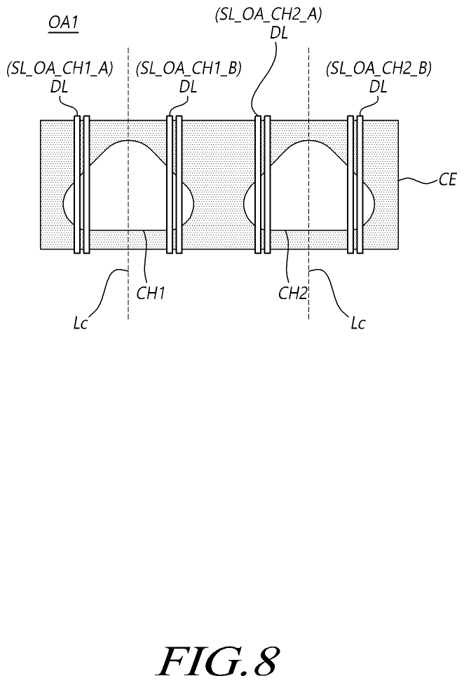

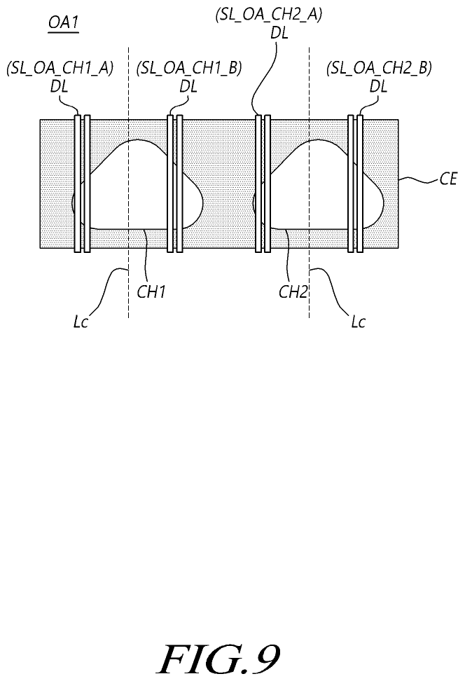

FIGS. 8 and 9 are views illustrating that common electrode holes CH are disposed in a first optical area OA1 of a display panel 110 according to embodiments of the disclosure.

FIG. 8 is an enlarged plan view illustrating a partial area in which two common electrode holes CH1 and CH2 are formed in FIG. 6 when there is no process variation, and FIG. 9 is an enlarged plan view illustrating a partial area in which two common electrode holes CH1 and CH2 are formed in FIG. 7 when there is a process variation.

For example, as illustrated in FIGS. 7 and 8, each of the plurality of common electrode holes CH1 and CH2 may have a symmetrical shape with respect to the column-wise center line Lc.

As another example, each of the plurality of common electrode holes CH may not have a symmetrical shape with respect to the column-wise center line Lc, but may have a symmetrical shape with respect to the row-wise center line.

As another example, each of the plurality of common electrode holes CH may not only have a symmetrical shape with respect to the column-wise center line Lc, but may also have a symmetrical shape with respect to the row-wise center line.

Referring to FIGS. 8 and 9, the plurality of common electrode holes CH formed in the common electrode CE may include a first common electrode hole CH1 and a second common electrode hole CH2.

Referring to FIGS. 8 and 9, the plurality of specific signal lines SL_OA may include a first specific signal line SL_OA_CH1_A overlapping the first common electrode hole CH1 and a second specific signal line SL_OA_CH2_A overlapping the second common electrode hole CH2.

Referring to FIG. 8, when there is no process variation, the size of the overlapping area between the first specific signal line SL_OA_CH1_A and the first common electrode hole CH1 may be the same as the size of the overlapping area between the second specific signal line SL_OA_CH2_A and the second common electrode hole CH2.

Referring to FIG. 9, even when there is a process variation, the size of the overlapping area between the first specific signal line SL_OA_CH1_A and the first common electrode hole CH1 may be the same as the size of the overlapping area between the second specific signal line SL_OA_CH2_A and the second common electrode hole CH2. Accordingly, the transmittance deviation between the plurality of common electrode holes CH included in the first optical area OA1 may be reduced or removed regardless of whether a process variation occurs.

Referring to FIGS. 8 and 9, the plurality of specific signal lines SL_OA may further include a third specific signal line SL_OA_CH1_B overlapping the first common electrode hole CH1 and a fourth specific signal line SL_OA_CH2_B overlapping the second common electrode hole CH2.

Referring to FIGS. 8 and 9, the first specific signal line SL_OA_CH1_A may be positioned on one side of the center line Le of the first common electrode hole CH1, and the third specific signal line SL_OA_CH1_B may be positioned on the other side of the center line Le of the first common electrode hole CH1.

Referring to FIGS. 8 and 9, the second specific signal line SL_OA_CH2_A may be positioned on one side of the center line Le of the second common electrode hole CH2, and the fourth specific signal line SL_OA_CH2_B may be positioned on the other side of the center line Lc of the second common electrode hole CH2.

Referring to FIG. 8, when there is no process variation, the first specific signal line SL_OA_CH1_A and the third specific signal line SL_OA_CH1_B may be symmetrically positioned with respect to the center line Lc of the first common electrode hole CH1.

Referring to FIG. 8, when there is no process variation, the spacing between the first specific signal line SL_OA_CH1_A and the center line Lc of the first common electrode hole CH1 and the spacing between the third specific signal line SL_OA_CH1_B and the center line Lc of the first common electrode hole CH1 may be the same.

Referring to FIG. 8, when there is no process variation, the size of the overlapping area between the first specific signal line SL_OA_CH1_A and the first common electrode hole CH1 and the size of the overlapping area between the third specific signal line SL_OA_CH1_B and the first common electrode hole CH1 may be the same.

Referring to FIG. 8, when there is no process variation, the second specific signal line SL_OA_CH2_A and the fourth specific signal line SL_OA_CH2_B may be symmetrically positioned with respect to the center line Lc of the second common electrode hole CH2.

Referring to FIG. 8, when there is no process variation, the spacing between the second specific signal line SL_OA_CH2_A and the center line Lc of the second common electrode hole CH2 may be the same as the spacing between the fourth specific signal line SL_OA_CH2_B and the center line Lc of the second common electrode hole CH2.

Referring to FIG. 8, when there is no process variation, the size of the overlapping area between the second specific signal line SL_OA_CH2_A and the second common electrode hole CH2 may be the same as the size of the overlapping area between the fourth specific signal line SL_OA_CH2_B and the second common electrode hole CH2.

Referring to FIG. 9, when there is a process variation, the first specific signal line SL_OA_CH1_A and the third specific signal line SL_OA_CH1_B may be positioned asymmetrically with respect to the center line Le of the first common electrode hole CH1.

Referring to FIG. 9, when there is a process variation, the spacing between the first specific signal line SL_OA_CH1_A and the center line Lc of the first common electrode hole CH1 and the spacing between the third specific signal line SL_OA_CH1_B and the center line Lc of the first common electrode hole CH1 may be different from each other.

Referring to FIG. 9, when there is a process variation, the size of the overlapping area between the first specific signal line SL_OA_CH1_A and the first common electrode hole CH1 and the size of the overlapping area between the third specific signal line SL_OA_CH1_B and the first common electrode hole CH1 may be different from each other.

Referring to FIG. 9, when there is a process variation, the second specific signal line SL_OA_CH2_A and the fourth specific signal line SL_OA_CH2_B may be positioned asymmetrically with respect to the center line Lc of the second common electrode hole CH2.

Referring to FIG. 9, when there is a process variation, the spacing between the second specific signal line SL_OA_CH2_A and the center line Lc of the second common electrode hole CH2 and the spacing between the fourth specific signal line SL_OA_CH2_B and the center line Le of the second common electrode hole CH2 may be different from each other.

Referring to FIG. 9, when there is a process variation, the size of the overlapping area between the second specific signal line SL_OA_CH2_A and the second common electrode hole CH2 may be different from the size of the overlapping area between the fourth specific signal line SL_OA_CH2_B and the second common electrode hole CH2.

The plurality of specific signal lines SL_OA may include a plurality of data lines DL. According to the examples of FIGS. 8 and 9, the first specific signal line SL_OA_CH1_A, the third specific signal line SL_OA_CH1_B, the second specific signal line SL_OA_CH2_A, and the fourth specific signal line SL_OA_CH2_B may be data lines DL.

Referring to FIG. 8, the display panel may be designed so that a distance between a first specific signal line SL_OA_CH1_A and an edge or shape inflection point of the first common electrode hole CH1 is a threshold distance or more, and a distance between a third specific signal line SL_OA_CH1_B and an edge or shape inflection point of the first common electrode hole CH1 is a threshold distance or more. Further, referring to FIG. 8, the display panel may be designed so that a distance between a second specific signal line SL_OA_CH2_A and an edge or shape inflection point of the second common electrode hole CH2 is a threshold distance or more, and a distance between a fourth specific signal line SL_OA_CH2_B and an edge or shape inflection point of the second common electrode hole CH2 is a threshold distance or more.

Accordingly, as illustrated in FIG. 9, even if a process variation occurs, the first specific signal line SL_OA_CH1_A and the third specific signal line SL_OA_CH1_B may still overlap the first common electrode hole CH1, and the second specific signal line SL_OA_CH2_A and the fourth specific signal line SL_OA_CH2_B may still overlap the second common electrode hole CH2.

Hereinafter, when the common electrode hole CH has various shapes, a line characteristic deviation reduction structure and a transmittance variation range reduction structure according to embodiments of the disclosure are exemplarily described again.

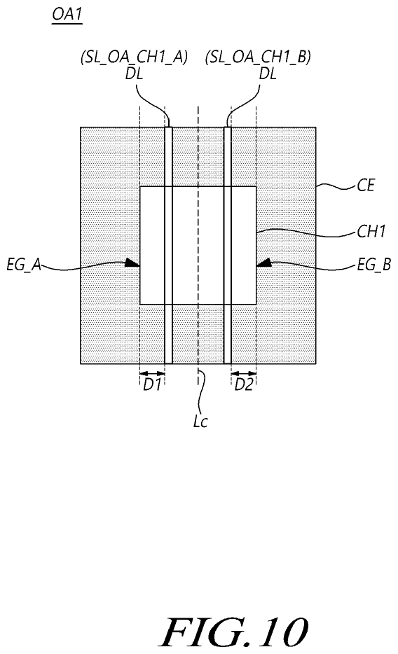

FIGS. 10 to 12 are views illustrating that common electrode holes CH are disposed in a first optical area OA1 of a display panel 110 according to embodiments of the disclosure.

Referring to FIG. 10, the first common electrode hole CH1 formed in the common electrode CE may have a symmetrical shape with respect to the column-wise center line Lc. For example, the first common electrode hole CH1 formed in the common electrode CE may have a rectangular shape. The first common electrode hole CH1 formed in the common electrode CE may have a plurality of edges EG_A and EG_B.

Referring to FIG. 10, the first specific signal line SL_OA_CH1_A may be positioned on one side of the center line Le of the first common electrode hole CH1, and the third specific signal line SL_OA_CH1_B may be positioned on the other side of the center line Lc of the first common electrode hole CH1.

Referring to FIG. 10, the first specific signal line SL_OA_CH1_A may be designed so that the distance D1 at which it is spaced apart from the edge EG_A of the first common electrode hole CH1 is the threshold distance or more, and the third specific signal line SL_OA_CH1_B may be designed so that the distance D2 at which it is spaced apart from the other edge EG_B of the first common electrode hole CH1 is the threshold distance or more.

Here, the threshold distance may be set to be greater than or equal to the maximum shift size of the common electrode hole CH when the process variation is maximized.

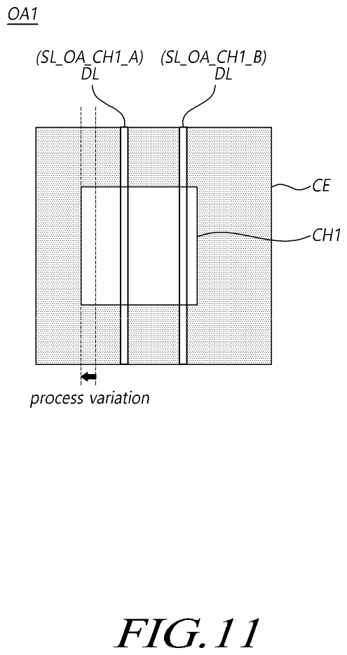

Referring to FIG. 11, when the display panel is manufactured, the process variation occurs, and thus the first common electrode hole CH1 may be formed to be shifted to one side compared to the designed position. Even if such a process variation occurs, when designed as shown in FIG. 10, both the first specific signal line SL_OA_CH1_A and the third specific signal line SL_OA_CH1_B may overlap the first common electrode hole CH1.

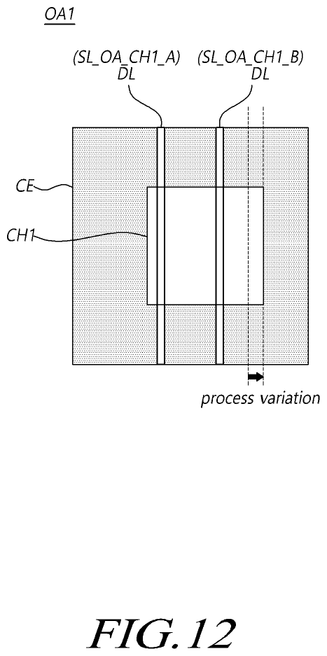

Referring to FIG. 12, when manufacturing the display panel, a process variation occurs, and the first common electrode hole CH1 may be formed to be shifted to the other side compared to the design position. Even if such a process variation occurs, when designed as shown in FIG. 10, both the first specific signal line SL_OA_CH1_A and the third specific signal line SL_OA_CH1_B may overlap the first common electrode hole CH1.

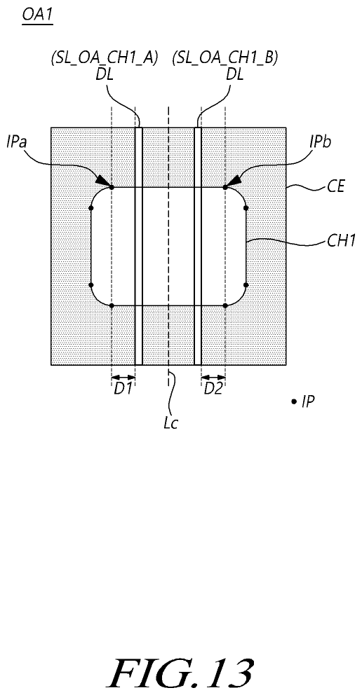

FIGS. 13 to 15 are views illustrating that common electrode holes CH are disposed in a first optical area OA1 of a display panel 110 according to embodiments of the disclosure.

Referring to FIG. 13, the first common electrode hole CH1 formed in the common electrode CE may have a symmetrical shape with respect to the column-wise center line Lc. For example, the first common electrode hole CH1 formed in the common electrode CE may have a rectangular shape with rounded corners. In this case, the first common electrode hole CH1 formed in the common electrode CE may have a plurality of shape inflection points IP in the corners.

Referring to FIG. 13, the first specific signal line SL_OA_CH1_A may be positioned on one side of the center line Le of the first common electrode hole CH1, and the third specific signal line SL_OA_CH1_B may be positioned on the other side of the center line Le of the first common electrode hole CH1.

Referring to FIG. 13, the first specific signal line SL_OA_CH1_A may be designed so that the distance D1 at which it is spaced apart from the first innermost shape inflection point IPa of the first common electrode hole CH1 is a threshold distance more, and the third specific signal line SL_OA_CH1_B may be designed so that the distance D2 at which it is spaced apart from the second innermost shape inflection point IPb of the first common electrode hole CH1 is equal to or greater than a threshold distance.

The first innermost shape inflection point IPa may be a shape inflection point IP positioned closest to the center line Lc among the plurality of shape inflection points IP positioned on one side of the center line Le of the first common electrode hole CH1.

The second innermost shape inflection point IPb may be a shape inflection point IP positioned closest to the center line Lc among the plurality of shape inflection points IP positioned on the other side of the center line Lc of the first common electrode hole CH1.

The threshold distance may be set to be greater than or equal to the maximum shift size of the common electrode hole CH when the process variation is maximized.

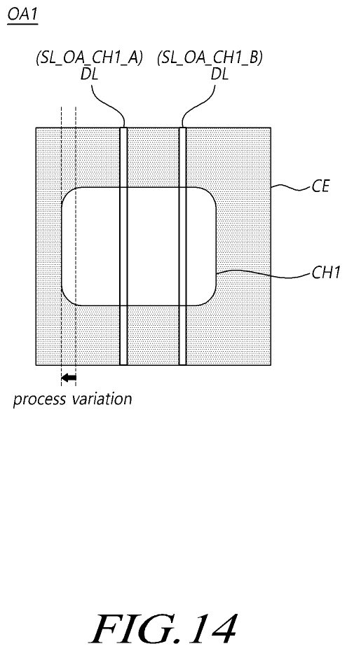

Referring to FIG. 14, when the display panel is manufactured, the process variation occurs, and thus the first common electrode hole CH1 may be formed to be shifted to one side compared to the designed position. Even if such a process variation occurs, when designed as shown in FIG. 13, both the first specific signal line SL_OA_CH1_A and the third specific signal line SL_OA_CH1_B may overlap the first common electrode hole CH1.

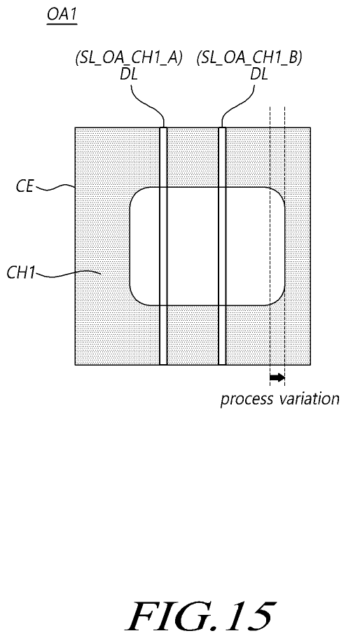

Referring to FIG. 15, when manufacturing the display panel, a process variation occurs, and the first common electrode hole CH1 may be formed to be shifted to the other side compared to the design position. Even if such a process variation occurs, when designed as shown in FIG. 13, both the first specific signal line SL_OA_CH1_A and the third specific signal line SL_OA_CH1_B may overlap the first common electrode hole CH1.

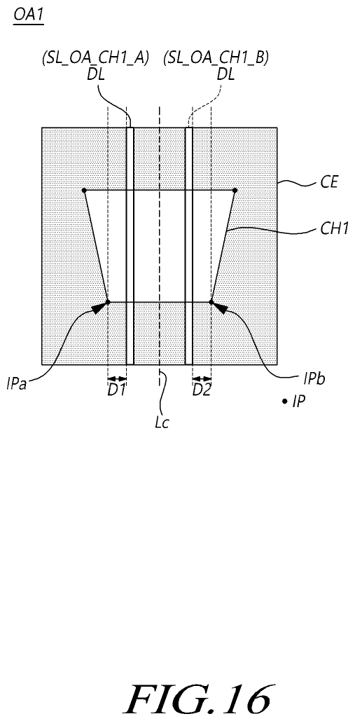

FIGS. 16 to 18 are views illustrating that common electrode holes CH are disposed in a first optical area OA1 of a display panel 110 according to embodiments of the disclosure.

Referring to FIG. 16, the first common electrode hole CH1 formed in the common electrode CE may have a symmetrical shape with respect to the column-wise center line Lc. For example, the first common electrode hole CH1 formed in the common electrode CE may have a trapezoidal shape. In this case, the first common electrode hole CH1 formed in the common electrode CE may have a plurality of shape inflection points IP at a corner.

Referring to FIG. 16, the first specific signal line SL_OA_CH1_A may be positioned on one side of the center line Le of the first common electrode hole CH1, and the third specific signal line SL_OA_CH1_B may be positioned on the other side of the center line Lc of the first common electrode hole CH1.

Referring to FIG. 16, the first specific signal line SL_OA_CH1_A may be designed so that the distance D1 at which it is spaced apart from the first innermost shape inflection point IPa of the first common electrode hole CH1 is a threshold distance more, and the third specific signal line SL_OA_CH1_B may be designed so that the distance D2 at which it is spaced apart from the second innermost shape inflection point IPa of the first common electrode hole CH1 is equal to or greater than a threshold distance.

The first innermost shape inflection point IPa may be a shape inflection point IP positioned closest to the center line Lc among the plurality of shape inflection points IP positioned on one side of the center line Le of the first common electrode hole CH1.

The second innermost shape inflection point IPb may be a shape inflection point IP positioned closest to the center line Lc among the plurality of shape inflection points IP positioned on the other side of the center line Lc of the first common electrode hole CH1.

The threshold distance may be set to be greater than or equal to the maximum shift size of the common electrode hole CH when the process variation is maximized.

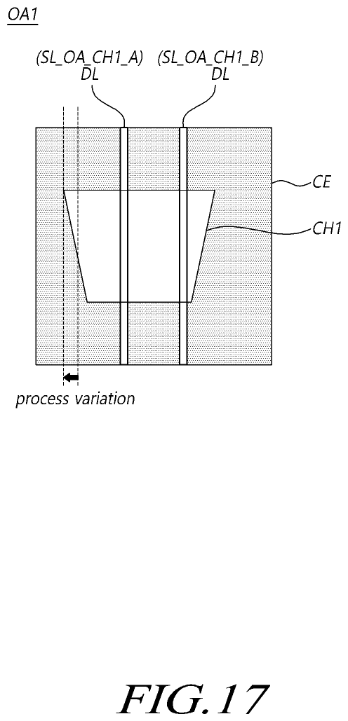

Referring to FIG. 17, when the display panel is manufactured, the process variation occurs, and thus the first common electrode hole CH1 may be formed to be shifted to one side compared to the designed position. Even if such a process variation occurs, when designed as shown in FIG. 16, both the first specific signal line SL_OA_CH1_A and the third specific signal line SL_OA_CH1_B may overlap the first common electrode hole CH1.

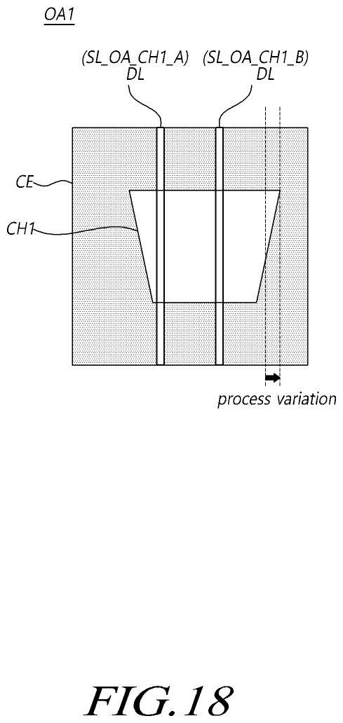

Referring to FIG. 18, when the display panel is manufactured, the process variation occurs, and thus the first common electrode hole CH1 may be formed to be shifted to the other side compared to the designed position. Even if such a process variation occurs, when designed as shown in FIG. 16, both the first specific signal line SL_OA_CH1_A and the third specific signal line SL_OA_CH1_B may overlap the first common electrode hole CH1.

As described above, the display panel 110 according to embodiments of the disclosure may have a line characteristic deviation reduction structure and a transmittance variation range reduction structure based on a structure in which a plurality of specific signal lines SL_OA overlap the common electrode hole CH.

Alternatively, the display panel 110 according to embodiments of the disclosure may have a line characteristic deviation reduction structure and a transmittance variation range reduction structure based on a structure in which the plurality of specific signal lines SL_OA do not overlap the common electrode hole CH. This is described below in more detail.

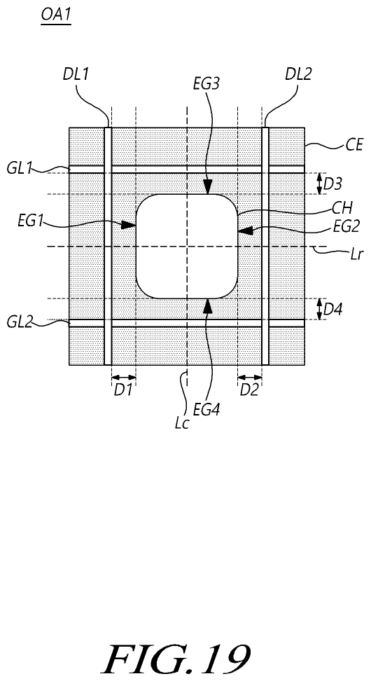

FIGS. 19 to 23 are views illustrating that common electrode holes CH are disposed in a first optical area OA1 of a display panel 110 according to embodiments of the disclosure.

Referring to FIG. 19, the common electrode hole CH formed in the common electrode CE may not only have a symmetrical shape with respect to the column-wise center line Lc, but may also have a symmetrical shape with respect to the row-wise center line Lr.

For example, the common electrode hole CH formed in the common electrode CE may have a rectangular shape with rounded corners. In this case, the common electrode hole CH formed in the common electrode CE may have four edges, e.g., first to fourth edges EG1, EG2, EG3, and EG4.

Referring to FIG. 19, the plurality of specific signal lines SL_OA may include a first data line DL1 positioned on one side of the column-wise center line Lc of the common electrode hole CH and a second data line DL2 positioned on the other side of the column-wise center line Lc of the common electrode hole CH.

Referring to FIG. 19, the plurality of specific signal lines SL_OA may further include a first gate line GL1 positioned on one side of the row-wise center line Lr of the common electrode hole CH and a second gate line GL2 positioned on the other side of the row-wise center line Lr of the common electrode hole CH.

Referring to FIG. 19, when the display panel is manufactured in the same state as designed (i.e., when no process variation occurs), the first and second data lines DL1 and DL2 and the first and second gate lines GL1 and GL2 do not overlap the common electrode hole CH.

Referring to FIG. 19, according to the line position design, the distance D1 between the first data line DL1 and the first edge EG1 may be a threshold distance or more, the distance D2 between the second data line DL2 and the second edge EG2 may be a threshold distance or more, the distance D3 between the first gate line GL1 and the third edge EG3 may be a threshold distance or more, and the distance D4 between the second gate line GL2 and the fourth edge EG4 may be a threshold distance or more.

The threshold distance may be set to be greater than or equal to the maximum shift size of the common electrode hole CH when the process variation is maximized.

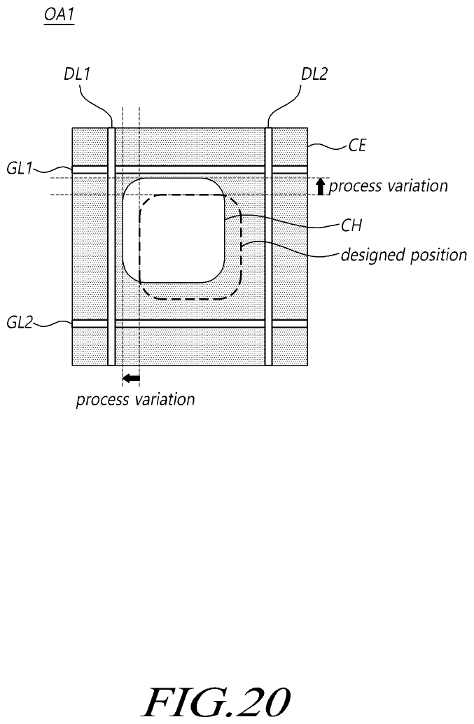

Referring to FIG. 20, when manufacturing the display panel, a process variation occurs, and the common electrode hole CH may be formed to be shifted left/up compared to the designed position. Even if such a process variation occurs, the first and second data lines DL1 and DL2 and the first and second gate lines GL1 and GL2 do not overlap the common electrode hole CH, as in the state in which the process variation does not occur (FIG. 19).

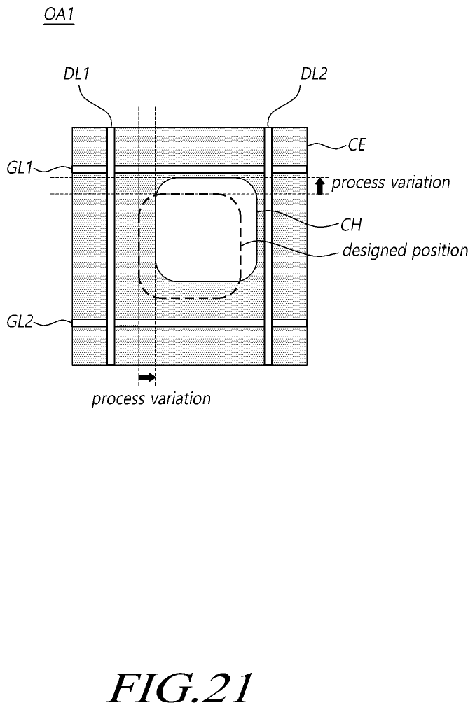

Referring to FIG. 21, when the display panel is manufactured, a process variation occurs, and the common electrode hole CH may be formed to be shifted right/up compared to a designed position. Even if such a process variation occurs, the first and second data lines DL1 and DL2 and the first and second gate lines GL1 and GL2 do not overlap the common electrode hole CH, as in the state in which the process variation does not occur (FIG. 19).

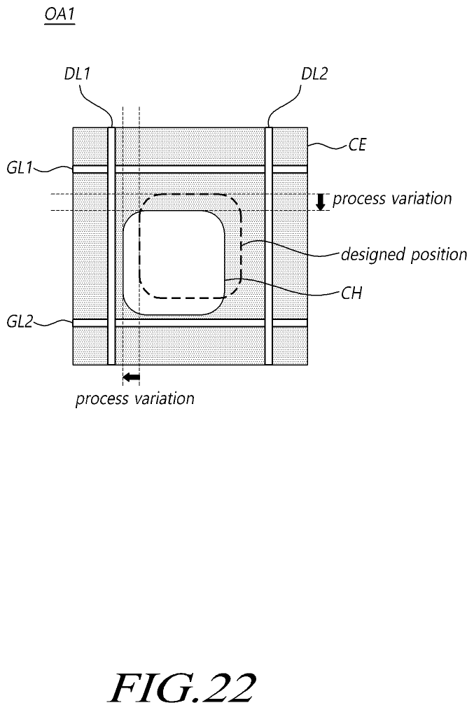

Referring to FIG. 22, when manufacturing the display panel, a process variation occurs, and the common electrode hole CH may be formed to be shifted left/down compared to the designed position. Even if such a process variation occurs, the first and second data lines DL1 and DL2 and the first and second gate lines GL1 and GL2 do not overlap the common electrode hole CH, as in the state in which the process variation does not occur (FIG. 19).

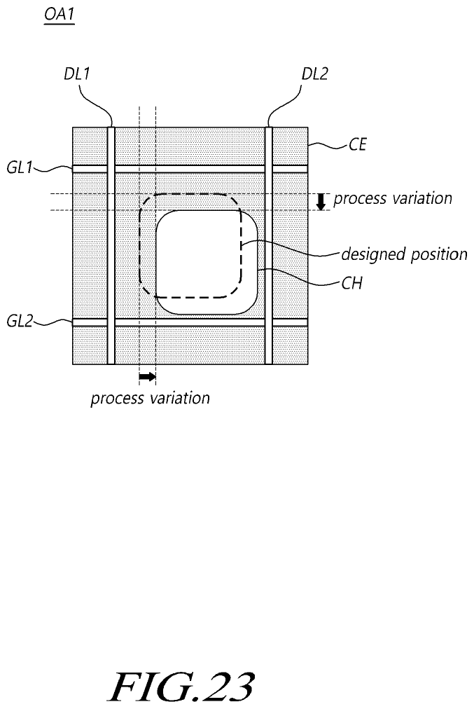

Referring to FIG. 23, when the display panel is manufactured, a process variation occurs, and the common electrode hole CH may be formed to be shifted right/down compared to a designed position. Even if such a process variation occurs, the first and second data lines DL1 and DL2 and the first and second gate lines GL1 and GL2 do not overlap the common electrode hole CH, as in the state in which the process variation does not occur (FIG. 19).

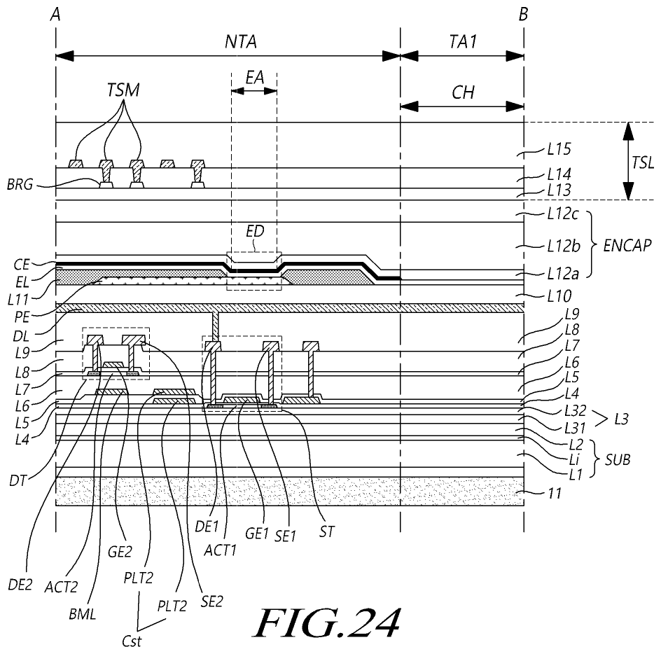

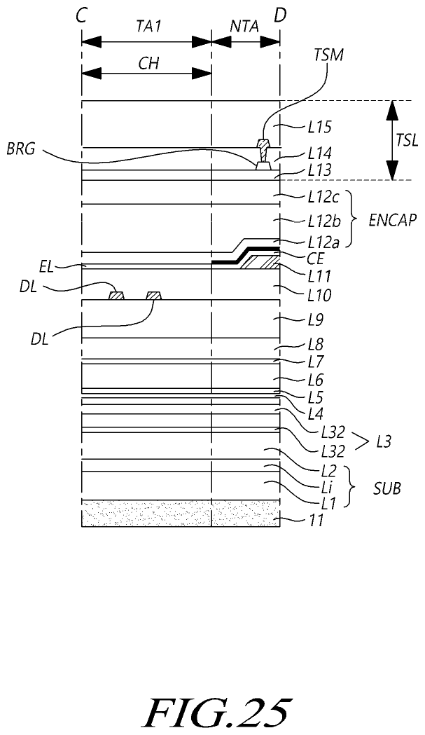

FIGS. 24 and 25 are cross-sectional views illustrating a partial area in a first optical area OA1 of a display panel 110 according to embodiments of the disclosure. FIG. 24 is a cross-sectional view taken along line A-B of FIG. 6, and FIG. 25 is a cross-sectional view taken along line C-D of FIG. 6.

Referring to FIG. 24, the display panel 110 according to embodiments of the disclosure may include a substrate SUB including a display area DA in which an image is displayed, a plurality of signal lines SL disposed on the substrate SUB, and a common electrode CE disposed on the substrate SUB.

Referring to FIG. 24, the first optical area OA1 may include a plurality of emission areas EA and a plurality of first transmissive areas TAL.

Referring to FIG. 24, the common electrode CE may include a plurality of common electrode holes CH. The plurality of common electrode holes CH may be positioned to correspond to the plurality of first transmissive areas TA1, respectively.

Referring to FIG. 24, the display panel 110 according to embodiments of the disclosure includes a pixel electrode PE disposed in one emission area EA among the plurality of emission areas EA included in the first optical area OA1, a driving transistor DT disposed in the first optical area OA1 and configured to supply a driving current to the pixel electrode PE, a capacitor Cst disposed in the first optical area OA1, a bank L11 disposed on the pixel electrode PE and having an opening, and a light emitting layer EL disposed between the bank L11 and the common electrode CE and positioned on a portion of the pixel electrode PE through the opening of the bank L11.

An area in which the pixel electrode PE, the light emitting layer EL, and the common electrode CE overlap may constitute one light emitting element ED and may correspond to one emission area EA.

The driving transistor DT and the capacitor Cst may be disposed in an area (i.e., the non-transmissive area NTA) other than the plurality of first transmissive areas TA1 in the first optical area OA1.

Referring to FIG. 24, the display panel 110 according to embodiments of the disclosure may further include a scan transistor ST disposed in an area other than the plurality of first transmissive areas TA1 in the first optical area OA1.

Referring to FIG. 24, the scan transistor ST may be connected to a data line DL which is one of the plurality of specific signal lines SL_OA.

Referring to FIGS. 24 and 25, the data line DL, which is one specific signal line SL_OA connected to the scan transistor ST among the plurality of specific signal lines SL_OA, may be disposed in a metal layer positioned between the pixel electrode PE and the source electrode and drain electrode of the driving transistor DT.

Referring to FIGS. 24 and 25, the display panel 110 according to embodiments of the disclosure may further include an encapsulation layer ENCAP disposed on the common electrode CE, and touch sensor metals TSM disposed on the encapsulation layer ENCAP and disposed in the normal area NA and the first optical area OA1.

Referring to FIGS. 24 and 25, the touch sensor metals TSM may overlap the bank L11. Among the touch sensor metals TSM, the touch sensor metals TSM disposed in the first optical area OA1 may be positioned in an area (i.e., the non-transmissive area NTA) other than the plurality of emission areas EA and the plurality of first transmissive areas TA1 in the first optical area OA1.

Hereinafter, the vertical structure of the display panel 110 is described in more detail with reference to FIGS. 24 and 25. FIG. 24 is a cross-sectional view taken along line A-B of FIG. 6, and FIG. 25 is a cross-sectional view taken along line C-D of FIG. 6.

Referring to FIGS. 24 and 25, the display panel 110 according to embodiments of the disclosure may include a transistor forming part, a light emitting element forming part, and an encapsulation part when viewed in a vertical structure, and may further include a touch sensor.

Referring to FIGS. 24 and 25, the display panel 110 according to embodiments of the disclosure may include a substrate SUB, a first buffer layer L3 on the substrate SUB, a first gate insulation film L4 on the first buffer layer L3, a first interlayer insulation film L5 on the first gate insulation film L4, a second buffer layer L6 on the first interlayer insulation film L5, a second gate insulation film L7 on the second buffer layer L6, a second interlayer insulation film L8 on the second gate insulation film L7, a first planarization layer L9 on the second interlayer insulation film L8, and a second planarization layer L10 on the first planarization layer L9.

The display panel 110 according to embodiments of the disclosure may further include a first gate metal layer positioned between the first gate insulation film L4 and the first interlayer insulation film L5, a first source-drain metal layer positioned between the second interlayer insulation film L8 and the first planarization layer L9, and a second source-drain metal layer positioned between the first planarization layer L9 and the second planarization layer L10.

The display panel 110 according to embodiments of the disclosure may further include a second gate metal layer between the first interlayer insulation film L5 and the second buffer layer L6, and a third gate metal layer between the second gate insulation film L7 and the second interlayer insulation film L8.

The display panel 110 according to embodiments of the disclosure may further include a first active layer ACT1 between the first buffer layer L3 and the first gate insulation film L4 and a second active layer ACT2 between the second buffer layer L6 and the second gate insulation film L7.

Referring to FIG. 24, the transistor forming part may include a substrate SUB, a first buffer layer L3 on the substrate SUB, various transistors DT and ST formed on the first buffer layer L3, a storage capacitor Cst, and various electrodes or signal lines.

Referring to FIG. 24, the substrate SUB may include a first substrate L1 and a second substrate L2, and may include an intermediate film L1 between the first substrate L1 and the second substrate L2. For example, each of the first substrate L1 and the second substrate L2 may include polyimide (PI). For example, the intermediate film Li may be an inorganic layer and may block moisture penetration.

Referring to FIG. 24, the first buffer layer L3 may be a single layer or multiple layers. When the first buffer layer L3 is multiple layers, the first buffer layer L3 may include a multi-buffer layer L31 and an active buffer layer L32.

Various transistors DT and ST, a storage capacitor Cst, and various electrodes or signal lines may be formed on the first buffer layer L3.

For example, the transistors DT and ST formed on the first buffer layer L3 may be formed of the same material and may be positioned on the same layers. Alternatively, as illustrated in FIG. 24, the driving transistor DT and the scan transistor ST may be formed of different materials and may be positioned on different layers.

Referring to FIG. 24, the driving transistor DT, the scan transistor ST, and the storage capacitor Cst may be included in a subpixel circuit unit SPC for driving the light emitting element ED included in the first optical area OA1.

The scan transistor ST may include an active layer ACT1, a gate electrode GE1, a source electrode SE1, and a drain electrode DEL.

The driving transistor DT may include an active layer ACT2, a gate electrode GE2, a source electrode SE2, and a drain electrode DE2.

The active layer ACT2 of the driving transistor DT may be positioned higher than the active layer ACT1 of the scan transistor ST. The upper transistor and the lower transistor may be distinguished according to the height of the active layer. The driving transistor DT may be referred to as an “upper transistor,” and the scan transistor ST may be referred to as a “lower transistor.”

The source electrode SE1 and the drain electrode DE1 of the scan transistor ST, which is the lower transistor, may be positioned in the “first source-drain metal layer.” The gate electrode GE1 of the scan transistor ST, which is the lower transistor, may be positioned in the “first gate metal layer.”

The source electrode SE2 and the drain electrode DE2 of the driving transistor DT, which is the upper transistor, may be positioned in the “first source-drain metal layer.” The gate electrode GE2 of the driving transistor DT, which is the upper transistor, may be positioned in a “third gate metal layer” higher than the first gate metal layer and the second gate metal layer.

The first buffer layer L3 may be disposed under the active layer ACT1 of the scan transistor ST, and the second buffer layer L6 may be disposed under the active layer ACT2 of the driving transistor DT. In other words, the active layer ACT1 of the scan transistor ST may be positioned on the first buffer layer L3, and the active layer ACT2 of the driving transistor DT may be positioned on the second buffer layer L6. Here, the second buffer layer L6 may be positioned higher than the first buffer layer L3.

The active layer ACT1 of the scan transistor ST may be disposed on the first buffer layer L3, and the first gate insulation film L4 may be disposed on the active layer ACT1 of the scan transistor ST. The gate electrode GE1 of the scan transistor ST may be disposed on the first gate insulation film L4, and the first interlayer insulation film L5 may be disposed on the gate electrode GE1 of the scan transistor ST.

Here, the active layer ACT1 of the scan transistor ST may include a channel area overlapping the gate electrode GE1, a source connection area positioned on one side of the channel area, and a drain connection area positioned on the other side of the channel area.

The second buffer layer L6 may be disposed on the first interlayer insulation film L5.

The active layer ACT2 of the driving transistor DT may be disposed on the second buffer layer L6, and the second gate insulation film L7 may be disposed on the active layer ACT2 of the driving transistor DT. The gate electrode GE2 of the driving transistor DT may be disposed on the second gate insulation film L7, and the second interlayer insulation film L8 may be disposed on the gate electrode GE2 of the driving transistor DT.

Here, the active layer ACT2 of the driving transistor DT may include a channel area overlapping the gate electrode GE2, a source connection area positioned on one side of the channel area, and a drain connection area positioned on the other side of the channel area.

The source electrode SE2 and the drain electrode DE2 of the driving transistor DT may be disposed on the second interlayer insulation film L8. Further, the source electrode SE1 and the drain electrode DE1 of the scan transistor ST may be disposed on the second interlayer insulation film L8.

The source electrode SE1 and the drain electrode DE1 of the scan transistor ST may be connected to the source connection area and the drain connection area, respectively, of the active layer ACT1 of the scan transistor ST through through-holes of the second interlayer insulation film L8, the second gate insulation film L7, the second buffer layer L6, the first interlayer insulation film L5, and the first gate insulation film L4.

The source electrode SE2 and the drain electrode DE2 of the driving transistor DT may be connected to the source connection area and the drain connection area, respectively, of the active layer ACT2 of the driving transistor DT through through-holes of the second interlayer insulation film L8 and the second gate insulation film L7.

The storage capacitor Cst may include a first capacitor electrode PLT1 and a second capacitor electrode PLT2.

The first capacitor electrode PLT1 of the storage capacitor Cst may be directly or indirectly electrically connected to the gate electrode GE2 of the driving transistor DT, and the second capacitor electrode PLT2 of the storage capacitor Cst may be directly or indirectly electrically connected to the source electrode SE2 of the driving transistor DT.

The first capacitor electrode PLT1 of the storage capacitor Cst may be positioned in the first gate metal layer formed of the first gate metal. The second capacitor electrode PLT2 of the storage capacitor Cst may be positioned in the second gate metal layer formed of the second gate metal.

Meanwhile, the lower metal BML may be disposed under the active layer ACT2 of the driving transistor DT. The lower metal BML may overlap the whole or part of the active layer ACT2 of the driving transistor DT. The lower metal BML may include the second gate metal of the second gate metal layer.

For example, the lower metal BML may be electrically connected to the gate electrode GE2 of the driving transistor DT. As another example, the lower metal BML may serve as a light shield to block the light introduced from thereunder. In this case, the lower metal BML may be electrically connected to the source electrode SE2 of the driving transistor DT.

Referring to FIG. 24, a first planarization layer L9 may be disposed on the driving transistor DT and the scan transistor ST. In other words, the first planarization layer L9 may be disposed on the source electrode SE2 and the drain electrode DE2 of the driving transistor DT and the source electrode SE1 and the drain electrode DE1 of the scan transistor ST.

Referring to FIG. 24, a second source-drain metal layer may be present between the first planarization layer L9 and the second planarization layer L10.

The source electrode SE2 of the driving transistor DT and the pixel electrode PE of the light emitting element ED may be electrically connected through a relay pattern formed in the second source-drain metal layer.

Referring to FIGS. 24 and 25, the data line DL passing through the first transmissive area TA1 may be formed in the second source-drain metal layer. In other words, the data line DL passing through the first transmissive area TA1 may include a second source-drain metal.

Referring to FIG. 24, the active layer ACT2 of the driving transistor DT which is the upper transistor and the active layer ACT1 of the scan transistor ST which is the lower transistor may include different semiconductor materials.

For example, the active layer ACT2 of the driving transistor DT, which is the upper transistor, may include an oxide semiconductor material. For example, the oxide semiconductor material may include indium gallium zinc oxide (IGZO), indium gallium zinc tin oxide (IGZTO), zinc oxide (ZnO), cadmium oxide (CdO), indium oxide (InO), zinc tin oxide (ZTO), and zinc indium tin oxide (ZITO).

For example, the active layer ACT1 of the scan transistor ST, which is the lower transistor, may include a semiconductor material different from the active layer ACT2 of the driving transistor DT, which is the upper transistor.

For example, the active layer ACT1 of the scan transistor ST, which is the lower transistor, may include a silicon-based semiconductor material. For example, the silicon-based semiconductor material may include low-temperature polycrystalline silicon (LTPS) or the like.

Referring to FIG. 24, a light emitting element forming part may be positioned on the second planarization layer L10.

The light emitting element forming part may include a light emitting element ED formed on the second planarization layer L10. The light emitting element ED may be disposed in the first optical area OA1.

The light emitting layer EL of the light emitting element ED may be locally formed only in the emission area EA. Alternatively, as illustrated in FIGS. 24 and 25, the light emitting layer EL of the light emitting element ED may be formed to extend to an outer area of the emission area EA.

Referring to FIG. 24, the light emitting element ED may be configured by overlapping the pixel electrode PE, the light emitting layer EL, and the common electrode CE. In other words, the light emitting element ED may be a portion where the pixel electrode PE, the light emitting layer EL, and the common electrode CE overlap each other.

The pixel electrode PE may be disposed on the second planarization layer L10.

The bank L11 may be disposed on the pixel electrode PE.

The bank LI1 may include a plurality of bank holes, and a portion of the pixel electrode PE may be exposed through the plurality of bank holes. In other words, the plurality of bank holes formed in the bank LI1 may overlap a portion of the pixel electrode PE.

The light emitting layer EL may be disposed on the bank L11. The light emitting layer EL may contact a portion of the pixel electrode PE through the bank hole.

At least one spacer may be present between the light emitting layer EL and the bank L11. The spacer may include the same material as the bank L11.

The common electrode CE may be disposed on the light emitting layer EL. The common electrode CE may include a plurality of common electrode holes CH. The plurality of common electrode holes CH formed in the common electrode CE may be disposed in the first optical area OA1.

The position of the common electrode hole CH may correspond to the position of the first transmissive area TA1.

Referring to FIGS. 24 and 25, an encapsulation part may be positioned on the cathode electrode CE. The encapsulation part may include an encapsulation layer ENCAP formed on the common electrode CE.

The encapsulation layer ENCAP may be a layer that prevents penetration of moisture or oxygen into the light emitting element ED disposed under the encapsulation layer ENCAP. In particular, the encapsulation layer ENCAP may prevent penetration of moisture or oxygen into the light emitting layer EL, which may include an organic film. Here, the encapsulation layer ENCAP may be composed of a single film or a multi-film structure.

The encapsulation layer ENCAP may include a first encapsulation layer L12a, a second encapsulation layer L12b, and a third encapsulation layer L12c.

For example, the encapsulation layer ENCAP may include inorganic films and organic films alternately disposed. In this case, e.g., the first encapsulation layer L12a and the third encapsulation layer L12c may be inorganic films, and the second encapsulation layer L12b may be an organic film. When the second encapsulation layer L12b is formed of an organic film, the second encapsulation layer L12b may serve as a planarization layer.

Meanwhile, the display panel 110 according to embodiments of the disclosure may include a touch sensor. In this case, the display panel 110 according to embodiments of the disclosure may include a touch sensor layer TSL on the encapsulation layer ENCAP.

The touch sensor layer TSL may include touch sensor metals TSM and bridge metals BRG, and may further include insulation film components such as the sensor buffer layer L13, the sensor interlayer insulation film L14, and the sensor protection layer L15.

The sensor buffer layer L13 may be disposed on the encapsulation layer ENCAP.

The bridge metals BRG may be disposed on the sensor buffer layer L13, and the sensor interlayer insulation film L14 may be disposed on the bridge metals BRG.

The touch sensor metals TSM may be disposed on the sensor interlayer insulation film L14. Some of the touch sensor metals TSM may be connected to the corresponding bridge metal BRG through a hole of the sensor interlayer insulation film L14.

The touch sensor metals TSM and the bridge metals BRG may be disposed in the normal area NA and may be disposed in the non-transmissive area NTA in the first optical area OA1.

When the display panel 110 has a top emission structure, if the touch sensor metals TSM and the bridge metals BRG are disposed in the non-transmissive area NTA in the first optical area OA1, the touch sensor metals TSM and the bridge metals BRG may be disposed not to overlap the emission area EA of the non-transmissive area NTA.

The plurality of touch sensor metals TSM may configure one touch electrode (or one touch electrode line) and may be disposed in a mesh form and electrically connected. Some of the touch sensor metals TSM and some others of the touch sensor metals TSM may be electrically connected through a bridge metal BRG, configuring one touch electrode (or one touch electrode line).

The sensor protection layer L15 may be disposed while covering the touch sensor metals TSM and the bridge metals BRG.

Meanwhile, when the display panel 110 is of a type that incorporates touch sensors, at least a portion of the touch sensor metal TSM positioned on the encapsulation layer ENCAP in the display area DA may extend and be disposed along the outer inclined surface of the encapsulation layer ENCAP to electrically connect to a pad positioned further outside the outer inclined surface of the encapsulation layer ENCAP. Here, the pad may be disposed in the non-display area NDA and may be a metal pattern to which the touch driving circuit 260 is electrically connected.

As described above, the display device 100 according to embodiments of the disclosure may further include the first optical electronic device 11 positioned under the substrate SUB and overlapping the first optical area OA1.

The first optical electronic device 11 may perform a selected (or predetermined) operation according to the first light of the first wavelength band of the light received through the first optical area OA1. For example, the first wavelength band may correspond to a visible light wavelength band or an infrared light wavelength band.

As described above, in the display panel 110 according to embodiments of the disclosure, the display area DA may further include a second optical area OA2 where light is transmitted, and the second optical area OA2 may include a plurality of emission areas EA and a plurality of second transmissive areas TA2.

In the display panel 110 according to embodiments of the disclosure, the common electrode CE may further include a plurality of additional common electrode holes CH positioned in the plurality of second transmissive areas TA2, respectively.

The plurality of signal lines SL may include a plurality of additional specific signal lines SL_OA passing through the second optical area OA2.

The plurality of additional specific signal lines SL_OA may include a first additional specific signal line overlapping a first additional common electrode hole CH included in the plurality of additional common electrode holes CH and a second additional specific signal line overlapping a second additional common electrode hole CH included in the plurality of additional common electrode holes CH.

As described above, the display device 100 according to embodiments of the disclosure may further include a first optical electronic device 11 positioned under the substrate SUB and overlapping the first optical area OA1, and a second optical electronic device 12 positioned under the substrate SUB and overlapping the second optical area OA2. The first optical electronic device 11 may be operated by receiving light passing through the substrate SUB in the first optical area OA1. The second optical electronic device 12 may be operated by receiving light passing through the through-hole in the second optical area OA2.

The first optical electronic device 11 may perform a selected (or predetermined) operation according to the first light of the first wavelength band of the light received through the first optical area OA1. The second optical electronic device 12 may perform a selected (or predetermined) operation according to the second light of the second wavelength band of the light received through the second optical area OA2.

For example, the first wavelength band may correspond to a visible light wavelength band, and the second wavelength band may correspond to an infrared light wavelength band.

The foregoing embodiments are briefly described below.

A display device according to embodiments of the disclosure may comprise a substrate including a display area displaying an image, a plurality of signal lines disposed on the substrate, and a common electrode disposed on the substrate.

The display area may include a first optical area where light is transmitted and a normal area positioned around the first optical area.

The normal area may include a plurality of emission areas.

The first optical area may include a plurality of emission areas and a plurality of first transmissive areas.

The common electrode may include a plurality of common electrode holes respectively positioned in the plurality of first transmissive areas.

The plurality of signal lines may include a plurality of normal signal lines not passing through the first optical area and a plurality of specific signal lines passing through the first optical area.

Each of the plurality of specific signal lines may overlap at least one of the plurality of common electrode holes.

The plurality of common electrode holes may include a first common electrode hole and a second common electrode hole.

The plurality of specific signal lines may include a first specific signal line overlapping the first common electrode hole and a second specific signal line overlapping the second common electrode hole.

A first overlapping area size between the first specific signal line and the first common electrode hole may be the same as a second overlapping area size between the second specific signal line and the second common electrode hole.

Here, that the first overlapping area size and the second overlapping area size are the same may mean that the first overlapping area size and the second overlapping area size are completely the same. Alternatively, that the first overlapping area size and the second overlapping area size are the same may mean that the first overlapping area size and the second overlapping area size are substantially the same although not completely the same. That the first overlapping area size and the second overlapping area size are substantially the same may mean that a difference between the first overlapping area size and the second overlapping area size is within a selected (or predetermined) range.

The plurality of specific signal lines may further include a third specific signal line overlapping the first common electrode hole and a fourth specific signal line overlapping the second common electrode hole.

The first specific signal line may be positioned on one side of a center line of the first common electrode hole, and the third specific signal line may be positioned on another side of the center line of the first common electrode hole.

The second specific signal line may be positioned on one side of a center line of the second common electrode hole, and the fourth specific signal line may be positioned on another side of the center line of the second common electrode hole.

The first overlapping area size between the first specific signal line and the first common electrode hole may be the same as a third overlapping area size between the third specific signal line and the first common electrode hole.

Here, that the first overlapping area size and the third overlapping area size are the same may mean that the first overlapping area size and the third overlapping area size are completely the same. Alternatively, that the first overlapping area size and the third overlapping area size are the same may mean that the first overlapping area size and the third overlapping area size are substantially the same although not completely the same. That the first overlapping area size and the third overlapping area size are substantially the same may mean that a difference between the first overlapping area size and the third overlapping area size is within a selected (or predetermined) range.

The second overlapping area size between the second specific signal line and the second common electrode hole may be the same as a fourth overlapping area size between the fourth specific signal line and the second common electrode hole.

Here, that the second overlapping area size and the fourth overlapping area size are the same may mean that the second overlapping area size and the fourth overlapping area size are completely the same. Alternatively, that the second overlapping area size and the fourth overlapping area size are the same may mean that the second overlapping area size and the fourth overlapping area size are substantially the same although not completely the same. That the second overlapping area size and the fourth overlapping area size are substantially the same may mean that a difference between the second overlapping area size and the fourth overlapping area size is within a selected (or predetermined) range.

A first spacing between the first specific signal line and the center line of the first common electrode hole may be the same as a third spacing between the third specific signal line and the center line of the first common electrode hole.

Here, that the first spacing and the third spacing are the same may mean that the first spacing and the third spacing are completely the same. Alternatively, that the first spacing and the third spacing are the same may mean that the first spacing and the third spacing are substantially the same although not completely the same. That the first spacing and the third spacing are substantially the same may mean that a difference between the first spacing and the third spacing is within a selected (or predetermined) range.

A second spacing between the second specific signal line and the center line of the second common electrode hole may be the same as a fourth spacing between the fourth specific signal line and the center line of the second common electrode hole.

Here, that the second spacing and the fourth spacing are the same may mean that the second spacing and the fourth spacing are completely the same. Alternatively, that the second spacing and the fourth spacing are the same may mean that the second spacing and the fourth spacing are substantially the same although not completely the same. That the second spacing and the fourth spacing are substantially the same may mean that a difference between the second spacing and the fourth spacing is within a selected (or predetermined) range.

The overlapping area size between the first specific signal line and the first common electrode hole may be different from the overlapping area size between the third specific signal line and the first common electrode hole.

The overlapping area size between the second specific signal line and the second common electrode hole may be different from the overlapping area size between the fourth specific signal line and the second common electrode hole.

A distance between the first specific signal line and an edge or shape inflection point of the first common electrode hole may be a threshold distance or more.

A distance between the second specific signal line and an edge or shape inflection point of the second common electrode hole may be the threshold distance or more.

The plurality of specific signal lines may include a plurality of data lines.

The plurality of specific signal lines may include a plurality of gate lines.

Each of the plurality of common electrode holes may have a symmetrical shape with respect to a column-wise center line.

Each of the plurality of common electrode holes may have a symmetrical shape with respect to a row-wise center line.

The display device may further comprise a first optical electronic device positioned under the substrate and overlapping the first optical area.

The first optical electronic device may perform a selected (or predetermined) operation according to first light of a first wavelength band of light received through the first optical area Here, the first wavelength band may correspond to a visible light wavelength band or an infrared light wavelength band.

In the display device according to embodiments of the disclosure, the display area may further include a second optical area where light is transmitted. The second optical area may include a plurality of emission areas and a plurality of second transmissive areas.

The common electrode may include a plurality of additional common electrode holes respectively positioned in the plurality of second transmissive areas.

The plurality of signal lines may include a plurality of additional specific signal lines passing through the second optical area.

The plurality of additional specific signal lines may include a first additional specific signal line overlapping a first additional common electrode hole included in the plurality of additional common electrode holes and a second additional specific signal line overlapping a second additional common electrode hole included in the plurality of additional common electrode holes.

The display device according to embodiments of the disclosure may further comprise a first optical electronic device positioned under the substrate and overlapping the first optical area and a second optical electronic device positioned under the substrate and overlapping the second optical area.

The first optical electronic device may perform a selected (or predetermined) operation according to first light of a first wavelength band of light received through the first optical area Here, the first wavelength band may correspond to a visible light wavelength band.

The second optical electronic device may perform a selected (or predetermined) operation according to second light of a second wavelength band of light received through the second optical area Here, the second wavelength band may correspond to an infrared light wavelength band.

Meanwhile, the display area may further include a second optical area where light is transmitted. Here, the second optical area may include a through-hole of the substrate. In contrast, the substrate may have no through-hole in the first optical area.

In this case, the display device according to embodiments of the disclosure may further comprise a first optical electronic device overlapping the first optical area and operated by receiving light passing through the substrate in the first optical area and a second optical electronic device operated by receiving light passing through the through-hole in the second optical area. For example, the first optical electronic device may be an infrared light detection sensor receiving light of an infrared light wavelength band to perform a detection operation, and the second optical electronic device may be a camera (image sensor) receiving light of a visible light wavelength band to perform a camera operation.

The display device according to embodiments of the disclosure may further comprise a pixel electrode disposed in one emission area among a plurality of emission areas included in the first optical area, a driving transistor disposed in the first optical area to supply a driving current to the pixel electrode, a capacitor disposed in the first optical area, a bank disposed on the pixel electrode and having an opening, and a light emitting layer disposed between the bank and the common electrode and positioned on a portion of the pixel electrode through the opening of the bank.

An area where the pixel electrode, the light emitting layer, and the common electrode overlap may correspond to the one emission area.

The driving transistor and the capacitor may be disposed in an area other than the plurality of first transmissive areas in the first optical area.

The display device according to embodiments of the disclosure may further comprise a scan transistor disposed in the area other than the plurality of first transmissive areas in the first optical area.

The scan transistor may be connected to one specific signal line among the plurality of specific signal lines.

The one specific signal line connected to the scan transistor may be disposed in a metal layer positioned between the pixel electrode and a source electrode and drain electrode of the driving transistor.

The display device according to embodiments of the disclosure may further comprise an encapsulation layer disposed on the common electrode and touch sensor metals disposed on the encapsulation layer and disposed in in the normal area and the first optical area.

The touch sensor metals may overlap the bank.

Among the touch sensor metals, touch sensor metals disposed in the first optical area may be positioned in the plurality of emission areas and the plurality of first transmissive areas in the first optical area.

A display panel according to embodiments of the disclosure may comprise a substrate including a display area displaying an image and a plurality of signal lines disposed on the substrate.

The display area may include a first optical area where light is transmitted and a normal area different from the first optical area.

The normal area may include a plurality of emission areas.

The first optical area may include a plurality of emission areas and a plurality of first transmissive areas.

The plurality of signal lines may include a normal signal line not passing through the first optical area and a specific signal line passing through the first optical area and disposed parallel to the normal signal line.

The specific signal line may have the same length as the normal signal line.

Here, that the specific signal line has the same length as the normal signal line may mean that that the length of the specific signal line is completely the same as the length of the normal signal line. Alternatively, that the specific signal line has the same length as the normal signal line may mean that the length of the specific signal line is substantially the same as the length of the normal signal line although not completely the same. That the length of the specific signal line is substantially the same as the length of the normal signal line may mean that a difference between the length of the specific signal line and the length of the normal signal line is within a selected (or predetermined) range.

The display panel according to embodiments of the disclosure may further comprise a common electrode disposed on the substrate.

The common electrode may include a plurality of first common electrode holes respectively positioned in the plurality of first transmissive areas. Each of the plurality of first common electrode holes may have a symmetrical shape with respect to a center line.

For example, the display area may further include a second optical area where light is transmitted, and the second optical area may include a plurality of emission areas and a plurality of second transmissive areas. In this case, in the second optical area, the substrate has no through-hole.

In this case, a common electrode disposed on the substrate may be further included, and the common electrode may include a plurality of second common electrode holes respectively positioned in the plurality of second transmissive areas.

Each of the plurality of second common electrode holes may have a symmetrical shape with respect to a center line.

As another example, the display area may further include a second optical area where light is transmitted, and the second optical area may include a through-hole of the substrate.

According to embodiments of the disclosure, there may be provided a display panel and a display device, in which an optical electronic device has a light transmission structure capable of normally receiving light (e.g., visible light, infrared light, or ultraviolet light), and the optical electronic device is not exposed to the front surface.

According to embodiments of the disclosure, there may be provided a display panel and a display device having a line characteristic deviation reduction structure between an optical area where light may be transmitted and a normal area where light is not transmitted. Accordingly, accurate display driving is possible and image quality may be enhanced. Further, a driving technique to reduce line characteristic deviation becomes unnecessary, allowing for high-efficiency driving and thus low-power design.

According to embodiments of the disclosure, there may be provided a display panel and a display device having a transmittance variation reduction structure in an optical area where light may be transmitted. Accordingly, the light transmission characteristics may be rendered uniform so that the operating performance (e.g., camera performance or detection performance) of the optical electronic device may be enhanced.

The above-described embodiments are merely examples, and it will be appreciated by one of ordinary skill in the art various changes may be made thereto without departing from the scope of the disclosure. Accordingly, the embodiments set forth herein are provided for illustrative purposes, but not to limit the scope of the disclosure, and should be appreciated that the scope of the disclosure is not limited by the embodiments.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

What is claimed:

1. A display device, comprising:
a substrate including a display area displaying an image, the display area including:
a first optical area from which light is transmitted, the first optical area including a plurality of emission areas and a plurality of first transmissive areas; and
a normal area positioned outside the first optical area, the normal area including a plurality of emission areas;
a plurality of signal lines disposed on the substrate, the plurality of signal lines including:
a plurality of normal signal lines not passing through the first optical area and disposed only in the normal area; and
a plurality of specific signal lines passing through the first optical area; and
a common electrode disposed on the substrate, the common electrode including a plurality of common electrode holes respectively positioned in the plurality of first transmissive areas, and
wherein each of the plurality of specific signal lines overlaps at least one of the plurality of common electrode holes.

2. The display device of claim 1, wherein the plurality of common electrode holes includes a first common electrode hole and a second common electrode hole,
wherein the plurality of specific signal lines includes a first specific signal line overlapping the first common electrode hole from a plan view, and a second specific signal line overlapping the second common electrode hole from a plan view, and
wherein a size of an overlapping area between the first specific signal line and the first common electrode hole is the same as a size of an overlapping area between the second specific signal line and the second common electrode hole.

3. The display device of claim 2, wherein the plurality of specific signal lines further include:
a third specific signal line overlapping the first common electrode hole from a plan view; and
a fourth specific signal line overlapping the second common electrode hole from a plan view, wherein the first specific signal line is positioned on one side of a center line of the first common electrode hole, and the third specific signal line is positioned on another side of the center line of the first common electrode hole, and
wherein the second specific signal line is positioned on one side of a center line of the second common electrode hole, and the fourth specific signal line is positioned on another side of the center line of the second common electrode hole.

4. The display device of claim 3, wherein the size of the overlapping area between the first specific signal line and the first common electrode hole is the same as a size of an overlapping area between the third specific signal line and the first common electrode hole, and
wherein the size of the overlapping area between the second specific signal line and the second common electrode hole is the same as a size of an overlapping area between the fourth specific signal line and the second common electrode hole.

5. The display device of claim 3, wherein the size of the overlapping area between the first specific signal line and the first common electrode hole is different from a size of an overlapping area between the third specific signal line and the first common electrode hole, and wherein the size of the overlapping area between the second specific signal line and the second common electrode hole is different from a size of an overlapping area between the fourth specific signal line and the second common electrode hole.

6. The display device of claim 2, wherein a distance between the first specific signal line and an edge or shape inflection point of the first common electrode hole is a threshold distance or more, and wherein a distance between the second specific signal line and an edge or shape inflection point of the second common electrode hole is the threshold distance or more.

7. The display device of claim 1, wherein the plurality of specific signal lines includes a plurality of data lines.

8. The display device of claim 1, wherein the plurality of specific signal lines includes a plurality of gate lines.

9. The display device of claim 1, wherein each of the plurality of common electrode holes has a symmetrical shape with respect to a column-wise center line.

10. The display device of claim 1, wherein each of the plurality of common electrode holes has a symmetrical shape with respect to a row-wise center line.

11. The display device of claim 1, further comprising a first optical electronic device positioned under the substrate and overlapping the first optical area, wherein the first optical electronic device performs a selected operation according to first light of a first wavelength band of light received through the first optical area, and wherein the first wavelength band corresponds to a visible light wavelength band or an infrared light wavelength band.

12. The display device of claim 1, wherein the display area further includes a second optical area where light is transmitted, wherein the second optical area includes a plurality of emission areas and a plurality of second transmissive areas, wherein the common electrode includes a plurality of additional common electrode holes respectively positioned in the plurality of second transmissive areas, wherein the plurality of signal lines include a plurality of additional specific signal lines passing through the second optical area, and wherein the plurality of additional specific signal lines include a first additional specific signal line overlapping a first additional common electrode hole included in the plurality of additional common electrode holes and a second additional specific signal line overlapping a second additional common electrode hole included in the plurality of additional common electrode holes.

13. The display device of claim 12, further comprising:
a first optical electronic device positioned under the substrate and overlapping the first optical area; and
a second optical electronic device positioned under the substrate and overlapping the second optical area, wherein the first optical electronic device performs a selected operation according to first light of a first wavelength band of light received through the first optical area, and the second optical electronic device performs a selected operation according to second light of a second wavelength band of light received through the second optical area, and wherein the first wavelength band corresponds to a visible light wavelength band, and the second wavelength band corresponds to an infrared light wavelength band.

14. The display device of claim 1, wherein the display area further includes a second optical area where light is transmitted, and wherein the second optical area includes a through-hole of the substrate.

15. The display device of claim 14, further comprising:
a first optical electronic device overlapping the first optical area and operated by receiving light passing through the substrate in the first optical area; and
a second optical electronic device operated by receiving light passing through the through-hole in the second optical area.

16. The display device of claim 1, further comprising:
a pixel electrode disposed in one emission area among a plurality of emission areas included in the first optical area;
a driving transistor disposed in the first optical area to supply a driving current to the pixel electrode;
a capacitor disposed in the first optical area;
a bank disposed on the pixel electrode and having an opening; and
a light emitting layer disposed between the bank and the common electrode and positioned on a portion of the pixel electrode through the opening of the bank, wherein an area where the pixel electrode, the light emitting layer, and the common electrode overlap corresponds to the one emission area, and wherein the driving transistor and the capacitor are disposed in an area other than the plurality of first transmissive areas in the first optical area.

17. The display device of claim 16, further comprising a scan transistor disposed in the area other than the plurality of first transmissive areas in the first optical area, wherein the scan transistor is connected to one specific signal line among the plurality of specific signal lines.

18. The display device of claim 17, wherein the one specific signal line connected to the scan transistor is disposed in a metal layer positioned between the pixel electrode and a source electrode and drain electrode of the driving transistor.

19. The display device of claim 16, further comprising:
an encapsulation layer disposed on the common electrode; and
touch sensor metals disposed on the encapsulation layer and disposed in in the normal area and the first optical area, wherein the touch sensor metals overlap the bank, and wherein among the touch sensor metals, touch sensor metals disposed in the first optical area are positioned in an area other than the plurality of emission areas and the plurality of first transmissive areas in the first optical area.

20. A display panel, comprising:
a substrate including a display area displaying an image, the display area including:
a first optical area from which light is transmitted, the first optical area including a plurality of emission areas and a plurality of first transmissive areas; and
a normal area different from the first optical area, the normal area including a plurality of emission areas; and
a plurality of signal lines disposed on the substrate, the plurality of signal lines including:
a normal signal line not overlapping the first optical area from a plan view; and
a specific signal line overlapping the first optical area from a plan view and disposed parallel to the normal signal line.

21. The display panel of claim 20, wherein the specific signal line has the same length as the normal signal line.

22. The display panel of claim 20, further comprising a common electrode disposed on the substrate, wherein the common electrode includes a plurality of first common electrode holes respectively positioned in the plurality of first transmissive areas, and wherein each of the plurality of first common electrode holes has a symmetrical shape with respect to a center line.

23. The display panel of claim 20, wherein the display area further includes a second optical area where light is transmitted, wherein the second optical area includes a plurality of emission areas and a plurality of second transmissive areas, and wherein the substrate has no through-hole in the second optical area.

24. The display panel of claim 23, further comprising a common electrode disposed on the substrate, wherein the common electrode includes a plurality of second common electrode holes respectively positioned in the plurality of second transmissive areas, wherein each of the plurality of second common electrode holes has a symmetrical shape with respect to a center line.

25. The display panel of claim 20, wherein the display area further includes a second optical area where light is transmitted, and wherein the second optical area includes a through-hole of the substrate.
